(19) United States
(12) Patent Application Publication
(10) Pub. No.: US 2024/0276846 A1
(43) Pub. Date: Aug. 15, 2024

(54) TOUCH STRUCTURE, DISPLAY SUBSTRATE AND DISPLAY PANEL

(71) Applicant: BOE Technology Group Co., Ltd., Beijing (CN)

(72) Inventors: Yingtao WANG, Beijing (CN); Xinxing WANG, Beijing (CN); Liyan LIU, Beijing (CN); Xuefei SUN, Beijing (CN); Jaegeon YOU, Beijing (CN); Qian JIA, Beijing (CN); Kuanjun PENG, Beijing (CN)

(21) Appl. No.: 18/023,396

(22) PCT Filed: Apr. 26, 2022
(86) PCT No.: PCT/CN2022/089322

§ 371 Date: Feb. 27, 2023

(30) Foreign Application Priority Data
Oct. 27, 2021 (CN) 202111256548.9

(51) Int. Cl. H10K 59/80; G06F 3/041; G06F 3/044; H10K 59/122; H10K 59/35; H10K 59/40

(52) U.S. Cl. CPC H10K 59/877; G06F 3/0412; G06F 3/0416; G06F 3/044; H10K 59/122; H10K 59/352; H10K 59/40; G06F 2203/04112

(57) ABSTRACT

Embodiments of the disclosure provide a touch structure, a display substrate and a display panel, where the touch structure includes: a metal mesh including a plurality of metal wires, where the metal mesh has a plurality of openings, each of the openings is surrounded by a plurality of metal wires, and the plurality of metal wires surrounding each of the openings have at least three different extending directions.

### CROSS REFERENCE TO RELATED APPLICATIONS

This application claims the benefit of Chinese Patent Application No. 202111256548.9, filed with the China National Intellectual Property Administration on Oct. 27, 2021 and entitled “Touch Structure, Display Substrate and Display Panel”, which is hereby incorporated by reference in its entirety.

### FIELD

The disclosure relates to the field of display technology, in particular to a touch structure, a display substrate and a display panel.

### BACKGROUND

With continuous development of electronic products, display panels with functions of touch and display can realize simple and flexible human-computer interaction, and therefore are widely used. The touch display panel includes, for example, a one glass solution (OGS) display panel, an on-cell display panel and an in-cell display panel.

### SUMMARY

In one aspect, a touch structure is provided, including: a metal mesh which includes a plurality of metal wires. The metal mesh has a plurality of openings, each of the openings is surrounded by a plurality of metal wires, and the plurality of metal wires surrounding each of the openings has at least three different extending directions.

In some embodiments, the opening is surrounded by N metal wires connected end to end, and the N metal wires have M different extending directions; N and M are integers, N≥5, and 3≤M≤N.

In some embodiments, the shape of each of the openings is asymmetric.

In some embodiments, any two of the N metal wires are asymmetrical to each other.

In some embodiments, at least part of the openings are symmetrical patterns, where a center line along a row direction of the opening which is a symmetrical pattern is an axis of symmetry.

In some embodiments, the metal wires surrounding the openings include two metal wires arranged in parallel with the center line and at least two groups of oblique metal wires arranged obliquely relative to the center line; and each group of oblique metal wires includes two metal wires arranged in parallel.

In some embodiments, the metal wires surrounding the openings further include at least two groups of vertical metal wires arranged vertically relative to the center line; and each group of the vertical metal wires includes two metal wires arranged in parallel.

In some embodiments, among the metal wires surrounding the openings, an included angle between the oblique metal wires and a vertical direction is greater than 0° and less than 90°.

In some embodiments, an included angle between the oblique metal wires and a vertical direction is greater than 0° and less than 45°.

In some embodiments, the metal mesh includes at least one type of openings, and each type of openings includes a plurality of openings of the same shape, and different types of openings have different shapes.

In some embodiments, the metal mesh includes a plurality of opening units, each opening unit includes one or more openings; and at least one opening in the opening unit is surrounded by more than eight metal wires connected end to end.

In some embodiments, the opening unit includes at least three openings, and at least three openings in the opening unit have different shapes and/or different areas.

In some embodiments, the shape of the metal wire includes a linear segment and/or an arc.

In some embodiments, the pattern of the opening includes at least one outwardly protruding convex angle and/or at least one inwardly indented concave angle.

In some embodiments, the width of the metal wire is 1 μm to 20 μm.

In some embodiments, the material of the metal wire is copper, argentum, nano carbon or graphene.

In some embodiments, a plurality of touch electrodes are provided, each touch electrode includes a metal mesh, and the plurality of touch electrodes are configured to be independently connected with the touch chip.

In some embodiments, a plurality of driving units and a plurality of sensing units insulated from each other are provided; each driving unit includes a plurality of driving electrodes arranged side by side along a first direction and a first connecting part electrically connecting two adjacent driving electrodes; each sensing unit includes a plurality of sensing electrodes arranged side by side along a second direction and a second connecting part electrically connecting two adjacent sensing electrodes; and the first direction and the second direction are intersected with each other. The touch structure includes a first metal layer, an insulating layer and a second metal layer which are stacked in sequence, where a plurality of via holes are arranged in the insulating layer. The driving electrode, the first connecting part and the sensing electrode are disposed in one of the first metal layer and the second metal layer, and the second connecting part is disposed in the other of the first metal layer and the second metal layer, and the second connecting part electrically connects two adjacent sensing electrodes through via holes. Or, the driving electrode, the second connecting part and the sensing electrode are arranged in one of the first metal layer and the second metal layer, the first connecting part is arranged in the other of the first metal layer and the second metal layer, and the first connecting part electrically connects two adjacent driving electrodes through via holes. The driving electrode, the sensing electrode, the first connecting part and the second connecting part include metal meshes.

In some embodiments, the driving electrode and/or the sensing electrode have/has an area of 9 mm² to 25 mm².

In another aspect, a display substrate is further provided, including: a base substrate and a display functional layer on the base substrate. The display functional layer includes a plurality of sub-pixels, and the contour of a light emitting region of each sub-pixel has sides in at least three different extending directions.

In some embodiments, the contour of the light emitting region consists of N sides connected end to end, the N sides have M different extending directions; N and M are integers, and N≥5, 3≤M≤N.

In some embodiments, the shape of the light emitting region of each sub-pixel is asymmetric.

In some embodiments, any two of the N sides are asymmetrical to each other.

In some embodiments, the contour of at least part of the light emitting region is a symmetrical pattern, where a center line along a row direction of the contour of the light emitting region that is a symmetrical pattern is an axis of symmetry.

In some embodiments, the display functional layer includes sub-pixels of a plurality of colors, and the contour of the light emitting region of the sub-pixel of at least one color consists of more than eight edges connected end to end.

In some embodiments, the light emitting regions of sub-pixels of different colors have different shapes and/or different areas.

In some embodiments, the display functional layer includes: a pixel defining layer provided with a plurality of light outlets, where each light outlet determines a light emitting region of a sub-pixel; and the shape of the light outlet is approximately the same as the shape of the light emitting region of the sub-pixel.

In some embodiments, the display functional layer includes a blue sub-pixel, a red sub-pixel, and a green sub-pixel. The area of the light emitting region of the blue sub-pixel is greater than the area of the light emitting region of the red sub-pixel, and the area of the light emitting region of the red sub-pixel is greater than the area of the light emitting region of the green sub-pixel. The pixel defining layer includes a first light outlet, a second light outlet and a third light outlet; where the first light outlet is configured to determine a light emitting region of the blue sub-pixel, the second light outlet is configured to determine a light emitting region of the red sub-pixel, and the third light outlet is configured to determine a light emitting region of the green sub-pixel. The area of the opening of the first light outlet is greater than the area of the opening of the second light outlet, and the area of the opening of the second light outlet is greater than the area of the opening of the third light outlet.

In still another aspect, a display panel is further provided, including: the display substrate of the above embodiments, and the touch structure of the above embodiments, where the touch structure is disposed on a light emitting side of the display substrate.

In some embodiments, an orthographic projection of the light emitting region of at least one sub-pixel of the display substrate on the base substrate of the display substrate is located within an orthographic projection of an opening of a metal mesh of the touch structure on the base substrate of the display substrate.

In some embodiments, an orthographic projection of the light emitting region of each sub-pixel on the base substrate is located within an orthographic projection of an opening of the metal mesh on the base substrate.

In some embodiments, a gap exists between a contour of an orthographic projection of the light emitting region of the at least one sub-pixel on the base substrate and a contour of an orthographic projection of one opening on the base substrate.

In some embodiments, the display substrate includes a plurality of pixel units, each pixel unit includes a plurality of sub-pixels; the metal mesh includes a plurality of opening units, and each opening unit includes one or more openings; an orthographic projection of a light emitting region of a plurality of sub-pixels of a pixel unit on the base substrate is located within an orthographic projection of one or more openings of one opening unit on the base substrate.

In some embodiments, the pixel unit includes a plurality of sub-pixels, and the opening unit includes one opening; and an orthographic projection of the light emitting region of the plurality of sub-pixels on the base substrate is located within an orthographic projection of the one opening on the base substrate. Or, the pixel unit includes a plurality of sub-pixels, and the opening unit includes two openings; an orthographic projection of the light emitting region of at least one sub-pixel on the base substrate is located within an orthographic projection of one of the two openings on the base substrate; and an orthographic projection of the light emitting regions of the remaining sub-pixels on the base substrate is located within an orthographic projection of the other one of the two openings on the base substrate.

In some embodiments, the pixel unit includes sub-pixels of X colors, the opening unit includes openings of X shapes, the sub-pixels of X colors are in one-to-one correspondence with the openings of X shapes, X is an integer, and X≥3. A first orthographic projection of an opening of a target shape on the base substrate covers a second orthographic projection of a light emitting region of a sub-pixel of a target color on the base substrate; the target shape is any shape among the X shapes, and the target color is a color corresponding to the target shape. The shape of the first orthographic projection is approximately the same as the shape of the second orthographic projection, and a gap exists between the contour of the second orthographic projection and the contour of the first orthographic projection.

In some embodiments, a vertical spacing between the contour of the first orthographic projection and the contour of the second orthographic projection is 8 μm to 12 μm.

### BRIEF DESCRIPTION OF THE DRAWINGS

In order to more clearly illustrate technical solutions in the disclosure, a brief introduction will be given below on the accompanying drawings which need to be used in some embodiments of the disclosure. Apparently, the accompanying drawings described below are merely the accompanying drawings of some embodiments of the disclosure, and other accompanying drawings may be obtained according to these drawings for those skilled in the art.

In addition, the accompanying drawings in the following description may be regarded as schematic diagrams and not as limiting the actual size of a product, the actual flow of a method, and the actual time sequence of a signal involved in the embodiments of the disclosure.

FIG. 1A to FIG. 1E shows top views of metal meshes according to some embodiments.

FIG. 2A shows a diagram of reflected light paths of a symmetrical opening.

FIGS. 2B-2D shows diagrams of reflected light paths of a plurality of metal wires surrounding each opening having at least three different extending directions.

FIGS. 3A-3C shows top views of an opening according to some embodiments.

FIG. 4 shows a top view of another opening according to some embodiments.

FIG. 5 shows a top view of another opening according to some embodiments.

FIG. 6 shows is a top view of a touch electrode according to some embodiments.

FIGS. 7A to FIG. 7G are enlarged views of edge areas of two touch electrodes according to some embodiments.

FIG. 8 shows a top view of a driving electrode and a sensing electrode according to some embodiments.

FIG. 9A shows is a sectional view of a touch structure according to some embodiments along a line AA′ in FIG. 8.

FIG. 9B shows a sectional view of a touch structure according to some embodiments along a line BB′ in FIG. 8.

FIG. 10 shows a sectional view of a display substrate according to some embodiments.

FIG. 11A to FIG. 11C shows top views of sub-pixels according to some embodiments.

FIG. 12A to FIG. 12C shows orthographic views of sub-pixels and metal meshes on a base substrate according to some embodiments.

FIG. 13A to FIG. 13C shows orthographic views of sub-pixels and metal meshes on a base substrate according to some embodiments.

FIG. 14 shows an orthographic view of sub-pixels and metal meshes on a base substrate according to some embodiments.

FIG. 15 shows an orthographic view of sub-pixels and metal meshes on a base substrate according to some embodiments.

FIG. 16 shows an orthographic view of sub-pixels and metal meshes on a base substrate according to some embodiments.

FIG. 17 shows a vertical interval of a first orthographic projection contour and a second orthographic projection contour according to some embodiments.

FIG. 18 shows a sectional view of a display panel according to some embodiments.

FIG. 19 shows a sectional view of a touch display apparatus according to some embodiments.

FIG. 20 shows a sectional view of another touch display apparatus according to some embodiments.

### DETAILED DESCRIPTIONS

A clear and complete description will be given below on technical solutions in some embodiments of the disclosure in combination with accompanying drawings, apparently, the described embodiments are merely a part but not all of the embodiments of the disclosure. Based on the embodiments provided in the disclosure, all the other embodiments obtained by those skilled in the art shall all fall within the protection scope of the disclosure.

Unless otherwise required in the context, throughout the specification and the claims, the term “comprise” and its other forms such as the singular form in third personal “comprises” and the present participle form “comprising” are interpreted to mean openness and inclusiveness, that is, “including but not limited to”. In the description of the specification, the terms “one embodiment”, “some embodiments”, “exemplary embodiments”, “example”, “specific example” or “some examples” and the like are intended to indicate that specific features, structures, materials or characteristics related to the embodiment or example are included in at least one embodiment or example of the disclosure. The schematic representations of the above terms do not necessarily refer to the same embodiment or example. Further, the particular features, structures, materials or characteristics may be included in any one or more embodiments or examples in any suitable manner.

The following terms “first” and “second” are merely used for descriptive purposes and cannot be understood as indicating or implying relative importance or implying the number of indicated technical features. Features thus defined as “first” and “second” may explicitly or implicitly include one or more such features. In the description of embodiments of the disclosure, “a plurality of” means two or more unless otherwise stated.

When some embodiments are described, “electrically connected” and “connected” and their extended expressions may be used. For example, the term “point connection” may be used in describing some embodiments to indicate that two or more components are in direct physical contact or electrical contact with each other. The embodiments disclosed herein are not necessarily limited to the content herein.

“A and/or B” includes the following three combinations: only A, only B and a combination of A and B.

The use of “configured” herein implies an open and inclusive language that does not exclude devices suitable for or configured to perform additional tasks or steps.

In addition, the use of “based on” means openness and inclusiveness, because a process, a step, calculations or other actions “based on” one or more of the conditions or values may be based on additional conditions or exceed the values in practice.

“Approximate” or “substantial” as used herein includes the values set forth and an average value within an acceptable deviation range of a particular value, wherein the acceptable deviation range is determined by those skilled in the art taking into account the measurements in question and the errors associated with the measurements of a particular quantity (i.e., limitations of a measurement system).

Exemplary embodiments are described herein with reference to sectional views and/or planar graphs as idealized exemplary drawings. In the accompanying drawings, the thicknesses of the layers and regions are enlarged for clarity. Therefore, variations in a shape relative to the accompanying drawings caused by, for example, manufacturing techniques and/or tolerances are envisaged. Therefore, the exemplary embodiments should not be interpreted as being limited to the shape of the regions shown herein but as including shape deviations caused by, for example, manufacturing. For example, an etched area shown as a rectangle will generally have curved features. Therefore, the regions shown in the accompanying drawings are schematic in nature and their shapes are not intended to show the actual shape of the region of the device and are not intended to limit the scope of the exemplary embodiments.

Along with rapid development of AMOLED (active matrix organic light-emitting diode) display apparatuss, full screen, narrow bezel, high resolution, curling wearing and folding have become important development directions of the AMOLED in the future.

Here, through a technology of fabricating a touch structure directly on an encapsulating layer of an OLED (organic light-emitting diode) display panel, lighter and thinner touch panels can be manufactured, and the technology can be applied to foldable and curlable OLED display apparatuss.

Based on considerations of reducing resistance and improving touch sensitivity, the touch electrode in the touch structure adopts metal meshes with advantages of small resistance, small thickness and fast reaction speed. In related technologies, the touch structure directly fabricated on an encapsulating layer of a display panel includes two types: a flexible metal layer on cell (FMLOC) type and a flexible single layer on cell (FSLOC) type. Compared with FMLOC type, the FSLOC type is more convenient for product thinning.

The inventor(s) of the disclosure found that a metal mesh of a touch structure on a light emitting side of a display substrate reflects the irradiated light to form continuous reflected light in a same direction, and human eyes receiving the reflected light can easily recognize the metal mesh, thereby reducing the display effect.

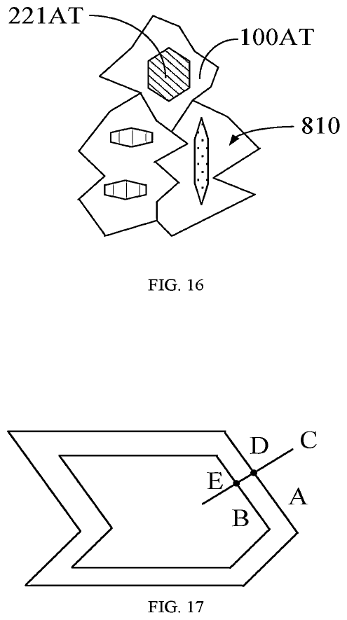

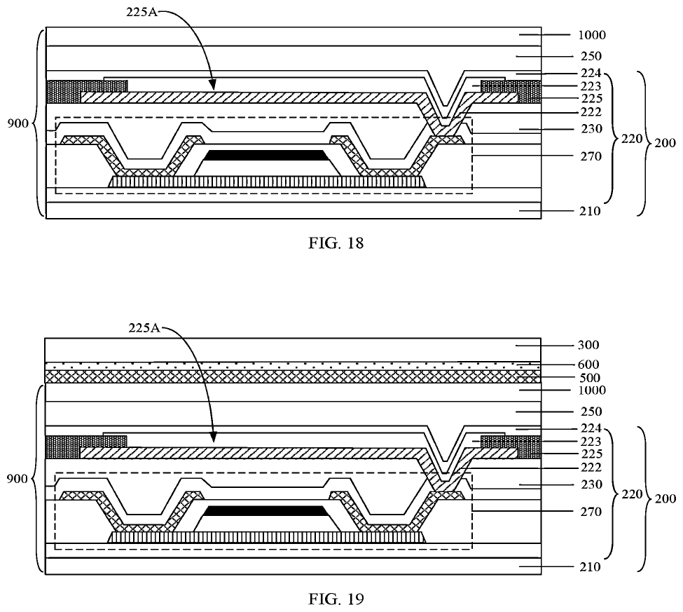

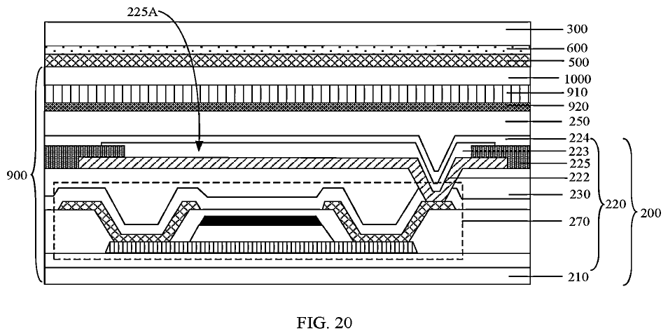

Based on this, as shown in FIG. 18, some embodiments of the disclosure provide a display panel 900 applied to a touch display apparatus, as shown in FIG. 19 and FIG. 20. The touch display apparatus may be an electroluminescent display apparatus or a photoluminescent display apparatus. When the display apparatus is an electroluminescent display apparatus, the electroluminescent display apparatus may be an organic light-emitting diode (OLED) display or quantum dot light emitting diode (QLED) display or a liquid crystal display (LCD) or electrophoretic display (EPD). When the touch display apparatus is a photoluminescent display apparatus, the photoluminescent display apparatus may be a quantum dot photoluminescent display apparatus.

In exemplary embodiments of the disclosure, OLED display apparatuss are taken as an example for illustration, however, it should not be considered to be limited to OLED display apparatuss. In some embodiments, as shown in FIG. 19 and FIG. 20, a main structure of the touch display apparatus includes a display panel 900, a touch structure 1000, an anti-reflection structure such as a polarizer 500, a first optically clear adhesive (OCA) layer 600 and a cover plate 300 disposed in sequence. In some embodiments, the anti-reflection structure may include a color filter and a black matrix.

Here the display panel 900 includes a display substrate 200 and an encapsulating layer 250 configured to encapsulate the display substrate 200. Herein, the encapsulating layer 250 may be an encapsulating film or an encapsulating substrate.

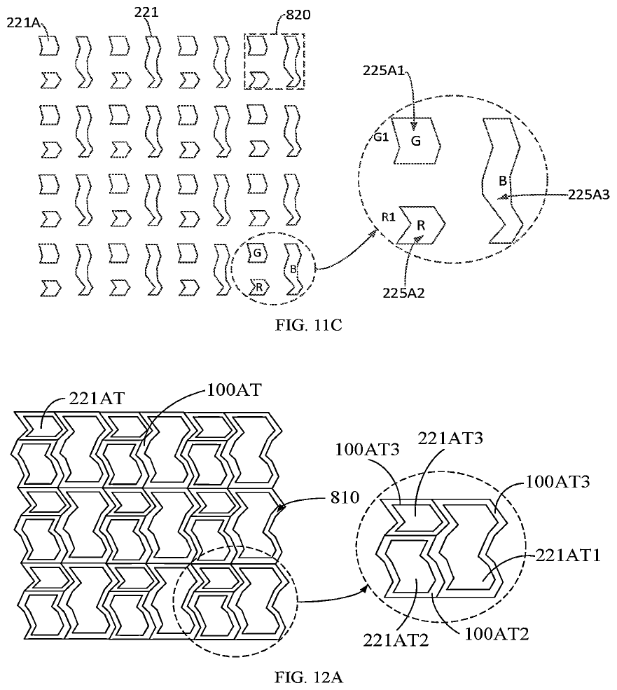

In some embodiments, as shown in FIG. 14, the touch structure 1000 of the display panel 900 is directly disposed on the encapsulating layer 250, such that the display substrate 200 can be regarded as a base substrate of the touch structure 1000, which is beneficial for realizing thinning of the display apparatus.

In some embodiments, the encapsulating layer 250 may include a first inorganic encapsulating layer, a first organic encapsulating layer and a second inorganic encapsulating layer, and may also be a stacked structure of at least one organic layer and at least one inorganic layer. In some embodiments, an anti-reflection structure may be formed in the encapsulating layer 250 to implement the anti-reflection, which further reduces the thickness of the display apparatus.

In some other embodiments, as shown in FIG. 20, the touch structure 1000 of the display panel 900 is arranged on a base substrate 910, and the base substrate 910 is attached to the encapsulating layer 250 through a second optically clear adhesive layer 920. The material of the base substrate 910 may be, for example, polyethylene terephthalate (PET), polyimide (PI), cyclo olefin polymer (COP) or the like.

As shown in FIG. 18 to FIG. 20, each sub-pixel of the above display substrate 200 includes a light emitting device and a driving circuit disposed on the base substrate 210. The driving circuit includes a plurality of thin film transistors 270. The light emitting device includes an anode 222, a light emitting layer 223 and a cathode 224. The anode 222 is electrically connected with a drain of the thin film transistor 270 which serves as a driving transistor among a plurality of thin film transistors 270 of the driving circuit.

In some embodiments, when the anode 222 is electrically connected with a drain of the thin film transistor 270 serving as a driving transistor among the plurality of thin film transistors 270 of a driving circuit, the anode is connected with the drain through an adaptor electrode, and the adaptor electrode is located between a film layer where the drain is disposed and a film layer where the anode is disposed.

The display substrate 200 further includes a pixel defining layer 225. The pixel defining layer 225 includes a plurality of light outlets 225A, and one light emitting device is arranged corresponding to one light outlet 225A.

In some embodiments, the display functional layer 220 includes a light emitting layer 223. In some other embodiments, besides the light emitting layer 223, the display functional layer 220 further includes one or more of an electron transporting layer (ETL), an electron injection layer (EIL), a hole transporting Layer (HTLt) and a hole injection layer (HIL).

As shown in FIG. 19 and FIG. 20, the display substrate 200 further includes at least one planarization layer 230 between the thin film transistor 270 and the anode 222. In some embodiments, at least one passivation layer is provided on the planarization layer 230.

When the touch display apparatus is an electroluminescent display apparatus, the touch display apparatus may be a top emission-type display apparatus, in this case, the anode 222 adjacent to the base substrate 210 is opaque and the cathode 224 away from the base substrate 210 is transparent or translucent; alternatively, the touch display apparatus may be a bottom emission-type display apparatus, in this case, the anode 222 adjacent to the base substrate 210 is transparent or translucent, and the cathode 224 away from the base substrate 210 is opaque; and the touch display apparatus may alternatively be a double-sided light emitting display apparatus, and in this case, both the anode 222 adjacent to the base substrate 210 and the cathode 224 away from the base substrate 210 are transparent or translucent.

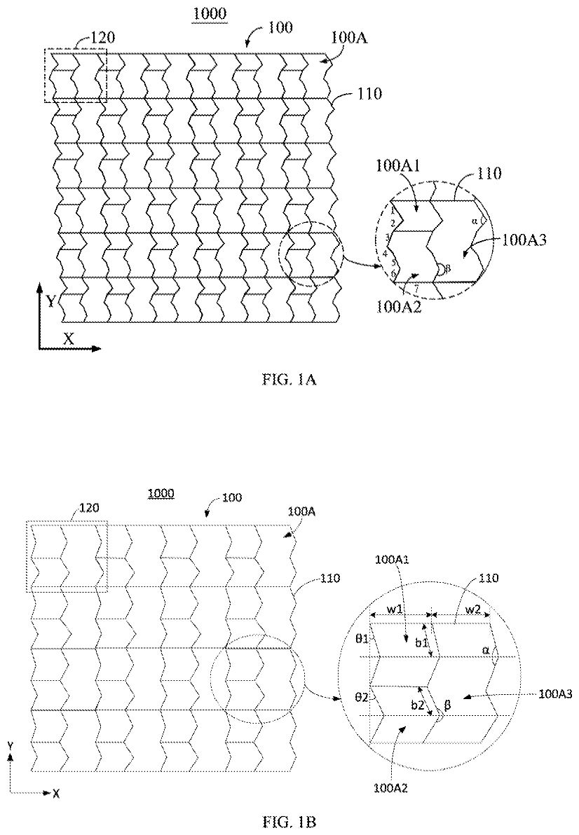

As shown in FIG. 1A to FIG. 1E, some embodiments of the disclosure provide a touch structure 1000, including: a metal mesh 100, and the metal mesh 100 includes a plurality of metal wires 110.

Here, the metal mesh 100 has a plurality of openings 100A, each of the openings 100A is surrounded by a plurality of metal wires 110, and the plurality of metal wires 110 surrounding each of the openings 100A have at least three different extending directions.

The touch area of the touch structure 1000 may be overlapped with the display area AA (which is also called active area) in the display substrate 200.

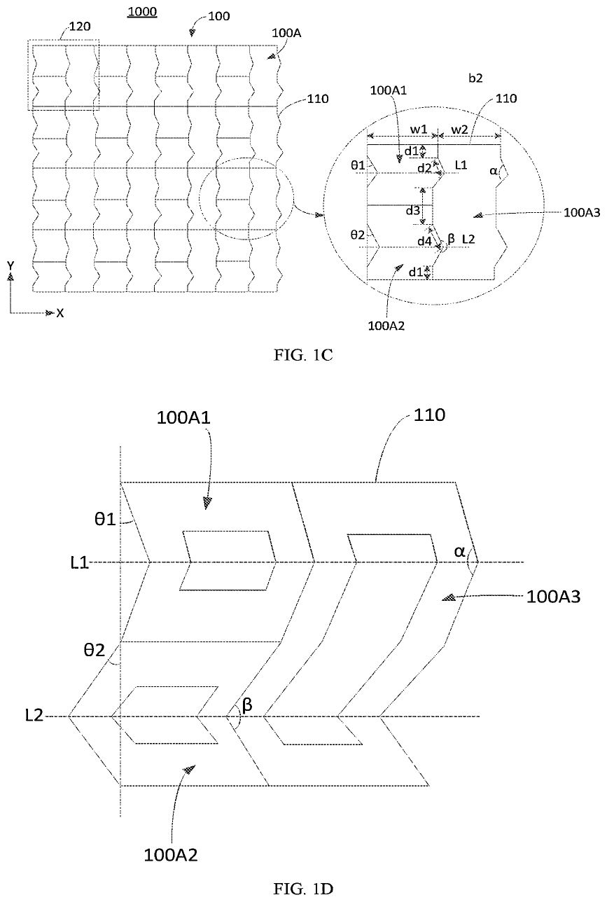

As shown in FIG. 2A to FIG. 2D, a hollow arrow at the bottom of the figure represents incident light and a black-lined arrow represents reflected light. As shown in FIG. 2A, when the opening is a symmetric, incident light in one direction is reflected through the opening, and the direction of the obtained reflected light is less, and the light in each reflected direction is more concentrated, such that continuous reflected light is easily formed in the same direction, thereby resulting in recognition of metal meshes by human eyes.

As shown in FIG. 2B to FIG. 2D, a plurality of metal wires surrounding each opening have at least three different extending directions, when the incident light in one direction is reflected through the opening, the reflected light has more directions, and the light rays in each reflection direction are dispersed to achieve an effect of quasi-scattering. The brightness of reflected light decreases and as to the visibility of the metal mesh, the reflectivity is lower after a polarizer is attached, and human eyes cannot perceive the reflected light, thereby eliminating or reducing the visibility of the metal mesh. In addition, the number of metal wires surrounding each opening is increased, at a boundary of touch electrodes (Tx and Rx), since the number and directions of the metal wires become more, more selections of cut can be implemented to minimize visibility (touch mura) of the metal mesh at the boundary.

Therefore, by setting the shape of the openings 100A in such a manner that the plurality of metal wires 110 surrounding each opening 100A have at least three different extending directions, the extending directions of the metal wires 110 in the metal mesh 100 can be increased, so that the direction of the reflected light of the metal mesh 100 as a whole is increased to achieve or approximate an effect of scattering light, thereby reducing or eliminating the phenomenon continuous light in the same direction reflected by the metal mesh 100, eliminating or alleviating the visibility of the metal mesh, and improving the display effect.

In addition, when external light is directed towards a display panel, reflection of the metal mesh 100 of a touch structure 1000 adjacent to a surface layer against the external light is the main reason causing Mura phenomenon (the brightness display is uneven, and various traces are shown). In some embodiments of the disclosure, through setting the shape of the above opening 100A in such a manner that the plurality of metal meshes 110 surrounding each opening 100A have at least three different extending directions, an effect of scattering reflected light is realized, and further the Mura phenomenon of the display panel 900 can be eliminated or reduced, and the display effect of the display panel 900 is improved.

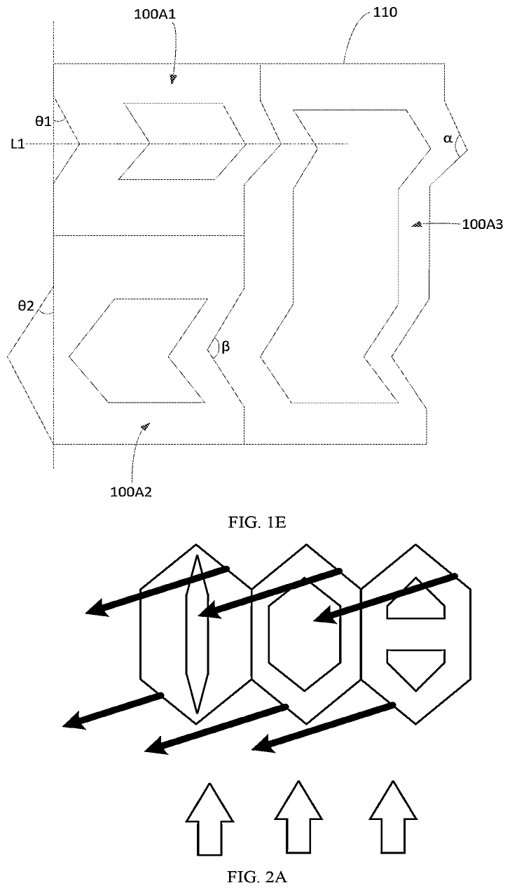

In some embodiments, at least one metal wire 110 of a plurality of metal wires 110 for an opening 100A may include at least one cut 110A, as shown in FIG. 3A to FIG. 3C. FIG. 3A is a schematic diagram based on FIG. 2B, FIG. 3B is a schematic diagram based on FIG. 2C, and FIG. 3C is a schematic diagram based on FIG. 2D. Here, end shapes of different cuts 110A may be the same or different. Exemplarily, the end shapes of two cuts 110A of the same metal wire 110 may be different; or the end shape of the cut 110A of the same metal wire 110 is the same, and the end shapes of the cuts 110A of different metal wires 110 are different; or the end shapes of the cuts 110A of a plurality of metal wires 110 are all the same; or the end shapes of the cuts 110A of a plurality of metal wires 110 are all different.

The widths of a plurality of metal wires 110 for one opening 100A may be the same or different. Exemplarily, the widths of a plurality of metal wires 110 for one opening 100A are the same; or the widths of a plurality of metal wires 110 for one opening 100A are all different; or the widths of part of the metal wires 110 among a plurality of metal wires 110 for one opening 100A are the same, the widths of the other part of metal wires 110 are the same, and the widths of two parts of the metal wires 110 are different.

It should be noted that in the case that the two metal wires 110 have cuts 110A of the same end shape, the end sizes of the cuts 110A are different when the widths of two metal wires 110 are different.

The design of the cut 110A enables a reduction of metal reflecting light for the opening 100A in FIG. 3A to FIG. 3C as compared to FIG. 2B to FIG. 2D, to further reduce the reflected light of the metal mesh 100, and eliminate or reduce the visibility of the metal mesh.

In some embodiments, the opening 100A is surrounded by N metal wires 110 connected end to end, and the N metal wires 110 have M different extending directions; N and M are integers, and N≥5, 3≤M≤N.

The two metal wires 110 having the same extending direction means that the two metal wires 110 are parallel to each other, the two metal wires 110 having different extending directions means that the two metal wires 110 are intersected, or the extending lines of the two metal wires 110 are intersected. Exemplarily, the number N of metal wires surrounding the opening 100A may be 5, 6, 7, 9, 10, 15 or 16. For example, when the number of metal wires surrounding the opening 100A is 5, there may be 3, 4 or 5 extending directions of the 5 metal wires. When M is equal to N, the extending directions of N metal wires surrounding the opening are all different; and when M is less than N, the extending directions of at least two metal wires are the same.

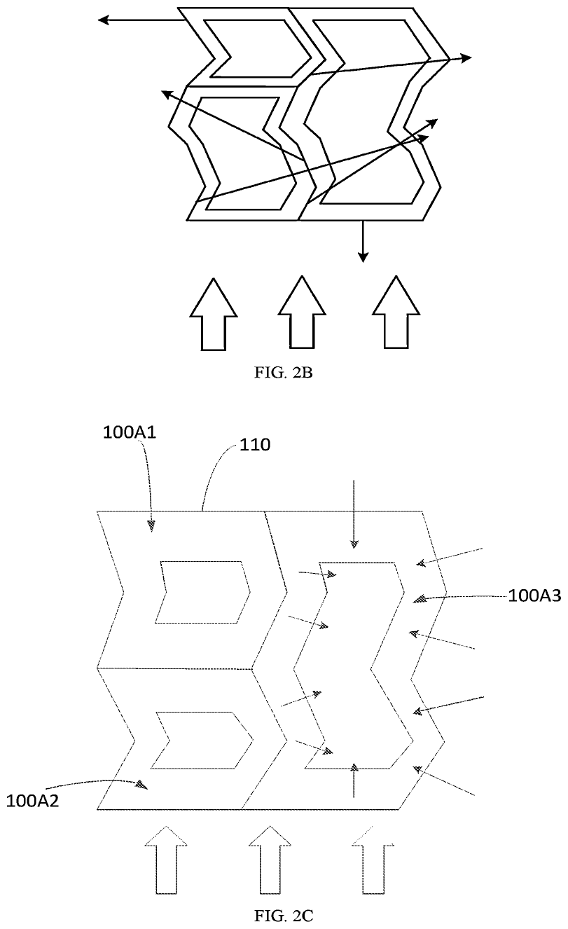

As shown in FIG. 4, points 1, 2 and 3 are marked on the same line and located at three positions on the metal line. In some embodiments of the disclosure, the metal conductive line is considered to include one linear metal wire with points 1 and 2 as endpoints and include another linear metal wire with points 2 and 3 as endpoints.

Exemplarily, the opening 100A (I) is surrounded by line segment 12, line segment 23, line segment 34, line segment 45, line segment 56, line segment 67 and line segment 71 connected end to end, and the opening 100A (II) is surrounded by line segment 23, line segment 38, line segment 89, line segment 90 and line segment 02 connected end to end. It should be noted that each of the above line segments represents a metal wire in the metal mesh 100.

When the number of metal wires 110 surrounding one opening 100A is greater than or equal to eight and the included angle between each side and a horizontal direction is greater than or equal to four types, the opening 100A can better achieve an effect of scattering light.

Exemplarily, as to the three openings 100A in FIG. 1A, the first type of opening 100A1 is surrounded by six sides, the second type of opening 100A2 is surrounded by ten sides, and the 30) third type of opening 100A3 is surrounded by fourteen sides. There are seven different included angles between the metal wires 110 of the three openings 100A and the horizontal direction, thereby better achieving an effect of scattering light.

Exemplarily, as to the three openings 100A in FIG. 1B, the first type of opening 100A1 is surrounded by six sides, the second type of opening 100A2 is surrounded by six sides, and the third type of opening 100A3 is surrounded by ten sides. There are at least five different included angles between the metal wires 110 of the three openings 100A and the horizontal direction, thereby better achieving an effect of scattering light.

Exemplarily, as to the three openings 100A in FIG. 1C, the first type of opening 100A1 is surrounded by ten sides, the second type of opening 100A2 is surrounded by ten sides, and the third type of opening 100A3 is surrounded by sixteen sides. There are at least six different included angles between the metal wires 110 of the three openings 100A and the horizontal direction, thereby better achieving an effect of scattering light.

Exemplarily, as to the three openings 100A in FIG. 1D, the first type of opening 100A1

is surrounded by six sides, the second type of opening 100A2 is surrounded by six sides, and the third type of opening 100A3 is surrounded by ten sides. There area at least five different included angles exist between the metal wires 110 of the three openings 100A and the horizontal direction, thereby better achieving an effect of scattering light.

Exemplarily, as to the three openings 100A in FIG. 1E, the first type of opening 100A1 is surrounded by ten sides, the second type of opening 100A2 is surrounded by ten sides, and the third type of opening 100A3 is surrounded by sixteen sides. There are at least six different included angles between the metal wires 110 of the three openings 100A and the horizontal direction, thereby better achieving an effect of scattering light.

The more the number of N and M, the more the directions of reflected light of the metal mesh, and the closer to the effect of scattering light. The phenomenon of forming continuous reflected light by the metal mesh in the same direction is eliminated or reduced, thereby being more convenient for eliminating or reducing visibility of the metal meshes, and improving the display effect.

In some embodiments, as shown in FIG. 1A, the shape of each opening 100A is asymmetric.

In some embodiments, as shown in FIG. 1A, any two metal wires 110 of the N metal wires 110 are asymmetrical to each other.

Asymmetry of two metal wires 110 may mean that the extending directions of the two metal wires 110 are symmetrical and the extending lengths are different; or the extending directions of the two metal wires are asymmetrical and the extending lengths are the same; or the extending directions of the two metal wires are asymmetrical and the extending lengths are different.

Any two metal wires 110 of the N metal wires 110 together surrounding the opening 100A are asymmetrical to each other, therefore, compared with the plurality of metal wires 110 which surround the opening 100A and include two symmetrical metal wires 110, the reflection directions of the metal wires 110 to the incident light can be increased, and the amount of reflected light in each reflection direction can be weakened, to further scatter light, thereby further increasing the directions of reflected light of the metal mesh 100 as a whole, facilitating to eliminate or reduce the visibility of human eyes to the metal mesh 100, and improving the display effect.

In some embodiments, as shown in FIG. 1B to FIG. 1E, at least part of the openings 100A are symmetrical, where a center line along a row direction of the opening 100A being symmetrical is an axis of symmetry. The opening 100A is set to be symmetrical, which may increase the aperture ratio of pixels.

Exemplarily, as shown in FIG. 1B, the first type of opening 100A1, the second type of opening 100A2 and the third type of opening 100A3 are all symmetrical, a center line L1 of the first type of opening 100A1 along a row direction is an axis of symmetry, a center line L2 of the second type of opening 100A2 along a row direction is an axis of symmetry, the center line L1 of the upper half of the third type of opening 100A3 along a row direction is an axis of symmetry, and the center line L2 of the lower half of the third type of opening 100A3 along a row direction is an axis of symmetry.

Exemplarily, as shown in FIG. 1C, the first type of opening 100A1 and the second type of opening 100A2 are both in a symmetrical pattern, the third type of opening 100A3 is in an asymmetrical pattern, the center line L1 of the first type of opening 100A1 along a row direction is an axis of symmetry, and the center line L2 of the second type of opening 100A2 along a row direction is an axis of symmetry.

Exemplarily, as shown in FIG. 1D, the first type of opening 100A1 and the second type of opening 100A2 are both in a symmetrical pattern, the third type of opening 100A3 is in an asymmetrical pattern, the center line L1 of the first type of opening 100A1 along a row direction is an axis of symmetry, and the center line L2 of the second type of opening 100A2 along a row direction is an axis of symmetry.

Exemplarily, as shown in FIG. 1E, the first type of opening 100A1 and the second type of opening 100A2 are both in a symmetrical pattern, and the third type of opening 100A3 is in an asymmetrical pattern. The center line L1 of the first type of opening 100A1 along a row direction is an axis of symmetry, and the center line L2 of the second type of opening 100A2 along a row direction is an axis of symmetry.

In some embodiments, as shown in FIG. 1B and FIG. 1D, the metal wires 110 surrounding the opening 100A include two metal wires 110 parallel to center lines (L1, L2) and at least two groups of oblique metal wires 110 disposed obliquely relative to the center lines (L1, L2); and each group of oblique metal wires 110 includes two metal wires 110 in parallel. The opening 100A surrounded hereby as shown in FIG. 1B and FIG. 1D is relatively regular, and is easy to increase the pixel aperture ratio.

In some embodiments, as shown in FIG. 1C and FIG. 1E, the metal wires 110 surrounding the opening 100A further include at least two groups of metal wires 110 vertical to the center lines (L1, L2); and each group of vertical metal wires 110 includes two metal wires 110 in parallel. The opening 100A surrounded hereby as shown in FIG. 1C and FIG. 1E is relatively regular, and is easy to increase the pixel aperture ratio.

In some embodiments, as shown in FIG. 1B and FIG. 1E, among the metal wires 110 surrounding the opening 100A, the included angles (θ1, θ2) formed between the obliquely arranged metal wires 110 and the vertical direction Y are greater than 0° and less than 90°.

Preferably, in some embodiments, as shown in FIG. 1B to FIG. 1E, to ensure the pixel aperture ratio and the size of the light emitting region, θ1 and θ2 are generally not required to be too large, so that the included angles (θ1, θ2) formed between the obliquely arranged metal wire 110 and the vertical direction Y are greater than 0° and less than 45°.

Exemplarily, θ1 and θ2 may be equal or may also be not equal.

Exemplarily, as shown in FIG. 1B, through adjusting lengths of w1, W2, b1 and b2, differentiation of aperture ratios of three sub-pixels R, G and B is realized, thereby ensuring better display quality.

Exemplarily, as shown in FIG. 1C, through adjusting lengths of w1, W2, di, d2, d3, d4, differentiation of aperture ratios of three sub-pixels R, G and B is realized, thereby ensuring better display quality.

Exemplarily, as shown in FIG. 1D and FIG. 1E, suppose that θ1 and θ2 are respectively 15° and 30°, while θ1 is shown on the right side of the dotted line and θ2 is shown on the left side of the dotted line. Similarly, through adjusting the angles of θ1 and θ2 and the side lengths of w1, w2, b1 and b2, differentiation of the aperture ratios of three sub-pixels of R, G and B can be realized.

In some embodiments, as shown in FIG. 1A to FIG. 1E, the metal mesh 100 includes at least one type of openings 100A, and each type of openings 100A includes a plurality of openings 100A of the same shape, and different types of openings 100A have different shapes.

The metal mesh 100 includes one or more types of openings 100A. Exemplarily, as shown in an enlarged view in FIG. 1A, the metal mesh 100 includes three types of openings 100A. The shape of the first type of opening 100A1 is an asymmetrical pattern with six sides, the shape of the second type of opening 100A2 is an asymmetrical pattern with ten sides, and the shape of the third type of opening 100A3 is an asymmetrical pattern with fourteen sides. The number of constituent edges of different types of openings 100A may also be the same but the shapes are different. The above is merely illustrated with different numbers of sides as an example.

Specifically, the lengths and angles of seven metal wires 110 shown in an enlarged view in FIG. 1A are taken as an example for illustration. The length of the metal wire 1 is 30 μm and the included angle between the metal wire 1 and the X direction is 60°, the length of the metal wire 2 is 24 μm and the included angle between the metal wire 2 and the X direction is 128°, the length of the metal wire 3 is 24 μm and the included angle between the metal wire 3 and the X direction is 110°, the length of the metal wire 4 is 14 μm and the included angle between the metal wire 4 and the X direction is 50°, the length of the metal wire 5 is 20 μm and the included angle between the metal wire 5 and the X direction is 70°, the length of the metal wire 6 is 28 μm and the included angle between the metal wire 6 and the X direction is 103°, and the length of the metal wire 7 is 60 μm and the included angle between the metal wire 7 and the X direction is 0°.

Here, the shapes of a plurality of openings 100A of the same type of openings 100A are the same, and the shapes of different types of openings 100A are different. In addition, the number of openings of different types of openings 100A may be the same or different, which is not limited herein.

In some embodiments, as shown in FIG. 1A to FIG. 1E, the metal mesh 100 includes a plurality of opening units 120, only one opening unit 120 is shown in FIG. 1D and FIG. 1E, each opening unit 120 includes one or more openings 100A; and at least one opening in the opening unit 120 is surrounded by more than eight metal wires 110 connected end to end.

The plurality of opening units 120 of the metal mesh 100 may be a plurality of identical opening units 120 or a plurality of different opening units 120, which is not limited herein.

The plurality of opening units 120 may be repeated in a display area, and there are no other openings 100A between two adjacent opening units 120. The plurality of opening units 120 may alternatively be distributed in the display area, and there are other openings 100A between adjacent opening units 120, which is not limited herein.

The number of openings 100A in one opening unit 120 may be 1, 3, 5 or the like. When one opening unit 120 includes a plurality of openings 100A, the shapes of the plurality of openings 100A may be the same or different, and the shapes of one part of the openings 100A may be the same while the shapes of the other part of the openings 100A may be different.

The greater the number of metal wires 110 surrounding the opening 100A, the more the directions of reflected light. A relatively good effect of scattering light can be obtained by more than eight metal wires. In each opening unit 120, at least one opening is surrounded by more than eight metal wires 110 connected end to end, thereby ensuring diversity of directions of reflected light of the opening unit 120, reducing the amount of reflected light in each direction of reflected light, and achieving an effect of quasi-scattering, so that human eyes cannot perceive reflected light, and the visibility of the metal mesh 100 can be easily eliminated or reduced, and the display effect can be improved.

In some embodiments, as shown in FIG. 1A to FIG. 1E, the opening unit 120 includes at least three openings 100A, and the at least three openings 100A in the opening unit 120 have different shapes and/or different areas.

The number of openings 100A in the opening unit 120 may be 3, 4, 5, etc. At least three openings 100A in the opening unit 120 may have different shapes and the same area, may have the same shape and different areas, or may have different shapes and different areas. When the shapes are different from each other and the areas are different from each, the same opening unit 120 does not have two openings 100A of the same shape, and does not have two openings 100A of the same area.

In a display substrate, one pixel unit includes at least three sub-pixels, exemplarily, a pixel unit includes a blue sub-pixel, a red sub-pixel and a green sub-pixel, or a pixel unit includes a blue sub-pixel, a red sub-pixel and two green sub-pixels, or a pixel unit includes a blue sub-pixel, a red sub-pixel, a green sub-pixel and a white sub-pixel.

This is similar to one opening unit 120 including at least three openings 100A, therefore, the opening unit 120 in the metal mesh 100 can correspond to the pixel unit in the display substrate. For example, the number of openings 100A in the opening unit 120 is the same as the number of sub-pixels in the pixel unit. In this way, the arrangement position of each opening 100A in the opening unit 120 can also be determined with reference to the arrangement position of the sub-pixels. Specifically, the arrangement position of each opening in the opening unit can be determined according to a mapping relationship between the opening 100A of one shape and a corresponding sub-pixel and the arrangement positions of the sub-pixels in the pixel unit.

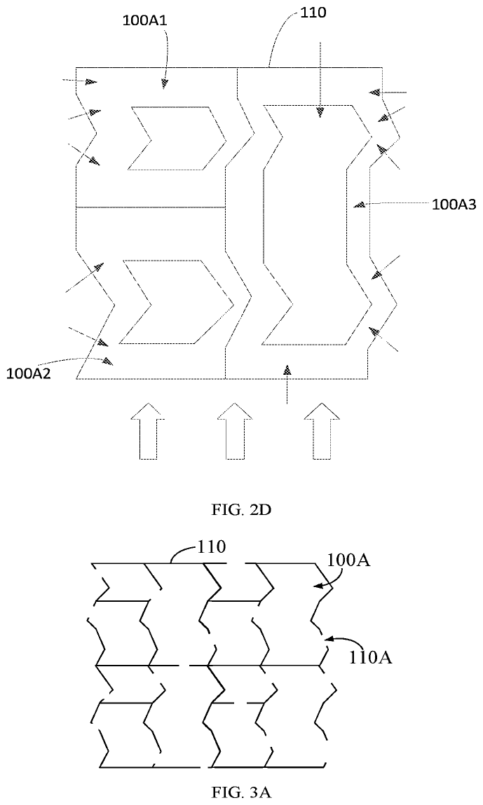

In some embodiments, as shown in FIG. 5, the shape of the above metal mesh 110 may include a linear segment i.e., the metal mesh 110 includes a linear metal wire 110L. The shape of the above metal wire 110 may include an arc, that is, the metal wire 110 includes an arc 110H.

N metal wires 110 surrounding one opening 100A may be all linear metal wires 110L, or may be all arc metal wires 110L, or part of the N metal wires 110 may be linear metal wires 110L and the remaining of the N metal wires 110 may be arc metal wires 110L. Here, when the metal wires 110 surrounding the opening 100A are all linear metal wires 110L, the metal mesh 100 is an asymmetrical polygon metal mesh (APM).

As shown in FIG. 1A to FIG. 1E, the opening 100A may include at least one outwardly protruding convex angle a. The convex angle a may be an included angle formed by connecting two linear metal wires 110L, may be an included angle formed by connecting two arc metal wires 110H, and may also be an included angle formed by connecting one linear metal wire 110L and one arc metal wire 110H. The angle of the side of the convex angle a facing the center of the opening 100A is greater than 0° and less than 180°, for example, 30°, 60°, 90°, 120° or 150°.

In addition, the opening 100A may include at least one inward concave angle β. The concave angle β may be an included angle formed by connecting two linear metal wires 110L, may be an included angle formed by connecting two arc metal wires 110H, and may also be an included angle formed by connecting one linear metal wire 110L and one arc metal wire 110H. The angle of the side of the concave angle β facing the center of the opening 100A is greater than 180° and less than 360°, for example, 210°, 240°, 270°, 300° or 330°.

In some embodiments, the material of the metal wire 110 includes at least one of copper (Cu), argentum (Ag), nano carbon or graphene. With the material of the metal wire 110 including argentums as an example, argentum may refer to elemental argentum, may also refer to nano argentum or other structural forms of argentum. Further, the material of the metal wire 110 may also be a compound including an argentum element, which is not limited herein.

With the material of the metal wire 110 including copper and nano carbon as an example, copper may refer to elemental copper, may also refer to nano copper or other structural forms of copper; nano carbon may refer to carbon nanotubes or carbon nanofibers, and may also refer to carbon nanospheres or other structural forms. The material of the metal wire 110 may include a mixture of any of the above copper forms and any of the above nano carbon forms.

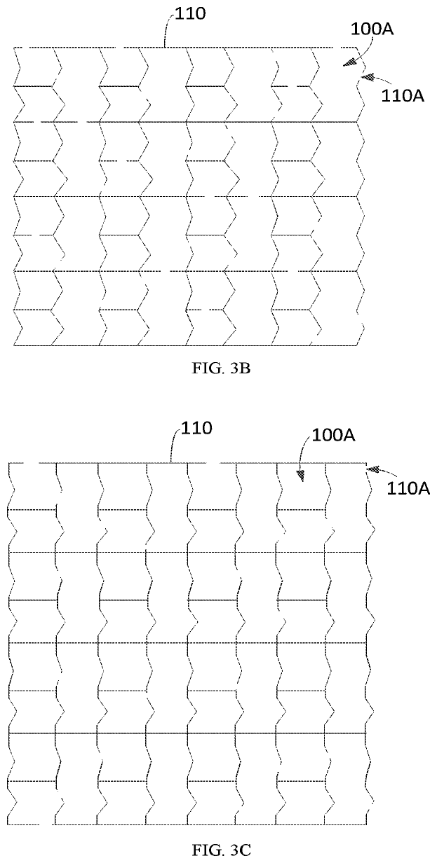

In some embodiments, as shown in FIG. 6, the touch structure may include a plurality of touch electrodes 410, each touch electrode 410 includes a metal mesh, and the plurality of touch electrodes are configured to be independently connected with the touch chip.

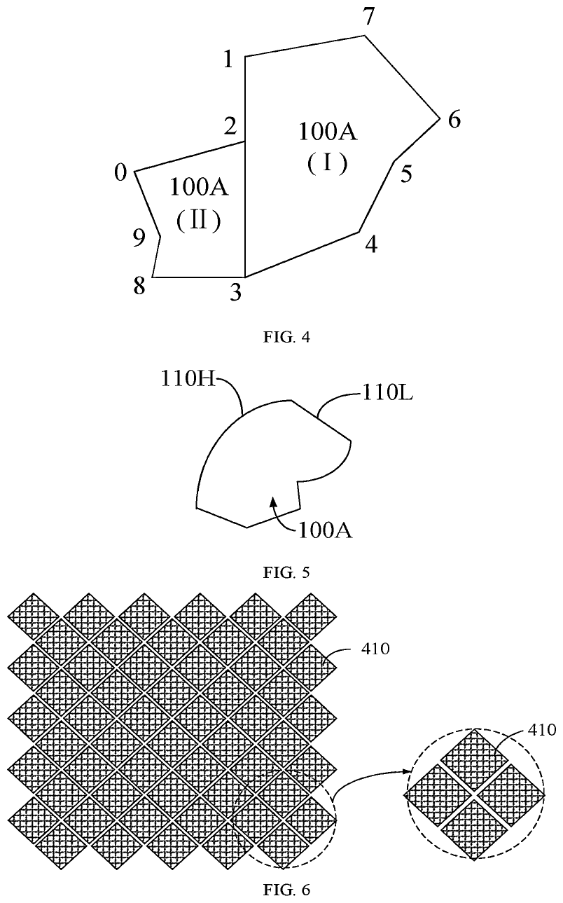

A plurality of touch electrodes 410 are insulated from each other, and the plurality of touch electrodes 410 are disposed within the display area. The shapes of the plurality of touch electrodes 410 may be identical, and the shape of the touch electrodes 410 may be rhombic or approximately rhombic, where “approximately rhombic” means that the shape of the touch electrode 410 is rhombic as a whole but is not limited to a standard rhombus. For example, boundaries of the touch electrodes 410 allow a non-linear shape (e.g., zigzag) as shown in FIG. 7A, FIG. 7D and FIG. 7G. FIG. 7A, FIG. 7D and FIG. 7G are enlarged views of edge regions of two touch electrodes 410 arranged horizontally. Thicker and irregular white lines on the left and right sides in FIG. 7A are boundaries of the two touch electrodes 410. The two white lines being arranged at intervals indicates that two adjacent touch electrodes 410 are arranged at intervals. A black filling structure in FIG. 7A is a sub-pixel; thicker and irregular black lines on the left and right sides in FIG. 7D are boundaries of the two touch electrodes 410, and the thicker and irregular black lines on the left and right sides in FIG. 7G are boundaries of the two touch electrodes 410. The two black lines being arranged at intervals indicates that two adjacent touch electrodes 410 are arranged at intervals.

As shown in FIG. 7B, FIG. 7C, FIG. 7E and FIG. 7F, FIG. 7B, FIG. 7C, FIG. 7E and FIG. 7F are enlarged views of a region between two groups of touch electrodes 410 arranged obliquely. Thicker and irregular black lines in FIG. 7B, FIG. 7C, FIG. 7E and FIG. 7F are boundaries between the two groups of touch electrodes 410.

In addition, the shape of the touch electrode 410 is not limited to a rhombic shape or an approximate rhombic shape, but may also be a rectangular shape, a strip shape or the like.

The touch electrode 410 including a metal mesh means that each touch electrode adopts a metal mesh structure. Compared with the adoption of an ITO (indium tin oxide) to form a planar electrode as a touch electrode 410, the touch electrode 410 of the metal mesh structure has small resistance and high sensitivity, and can improve the touch sensitivity of the touch display panel. Moreover, the touch electrodes 410 with a metal mesh structure have high mechanical strength, and can reduce weight of the touch display panel. When the touch display panel is applied to a display apparatus, thinning of the display apparatus can be realized.

A plurality of touch electrodes 410 including a metal mesh structure may be disposed on the same metal layer, i.e., an FSLOC structure, which facilitates thinning of the display apparatus.

Each touch electrode 410 is electrically connected with a touch chip independently, and the touch chip provides voltage to the touch electrode 410, so that the touch electrodes 410 can independently form capacitance with the ground. The touch points in the display area are determined by sensing changes of a plurality of capacitors.

Here, the metal wire of the metal mesh in the touch electrode 410 may be disposed to be align with a gap between the light emitting regions 221A of the plurality of sub-pixels 221 in the display area, thereby preventing the metal mesh from shielding emission of light, and ensuring the light emitting efficiency of the display apparatus.

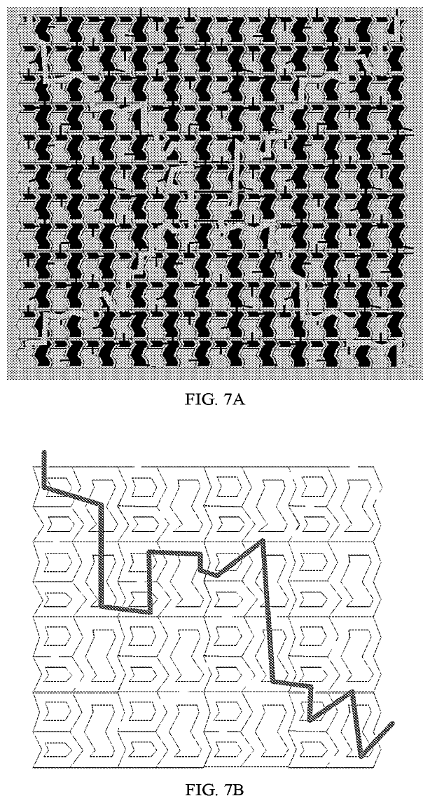

In some embodiments, as shown in FIG. 8, the touch structure may include a plurality of driving units 510 and a plurality of sensing units 520 insulated from each other; each driving unit 510 includes a plurality of driving electrodes 511 arranged side by side along a first direction X and a first connecting part 512 electrically connecting two adjacent driving electrodes 511; each sensing unit 520 includes a plurality of sensing electrodes 521 arranged side by side along a second direction Y and a second connecting part 522 electrically connecting two adjacent sensing electrodes 521. The first direction X and the second direction Y are intersected with each other.

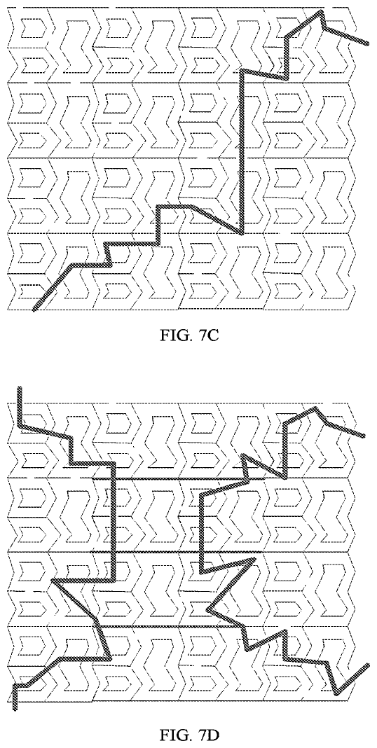

As shown in FIG. 9A and FIG. 9B, the touch structure includes a first metal layer 610, an insulating layer 620 and a second metal layer 630 which are stacked in sequence, and a plurality of via holes 621 are arranged in the insulating layer 620.

Exemplarily, the driving electrode 511, the first connecting part 512 and the sensing electrode 521 are arranged in one of the first metal layer 610 and the second metal layer 630, and the second connecting part 522 is arranged in the other of the first metal layer 610 and the second metal layer 630, and the second connecting part 522 electrically connects two adjacent sensing electrodes 521 through via holes 621.

Exemplarily, the driving electrode 511, the second connecting part 522 and the sensing electrode 521 are arranged in one of the first metal layer 610 and the second metal layer 630, and the first connecting part 512 is arranged in the other of the first metal layer 610 and the second metal layer 630, and the first connecting part 512 electrically connects two adjacent driving electrodes 511 through via holes 621.

Exemplarily, the driving electrode 511, the sensing electrode 521, the first connecting part 512 and the second connecting part 522 include metal meshes. The design described in the above embodiments is adopted for the shape of the opening and related arrangement of the metal mesh, such that the directions of reflected light of the touch structure 1000 can be increased, thereby reducing the amount of reflected light in each direction of reflected light, and achieving an effect of quasi-scattering, therefore, human eyes cannot perceive reflected light, thereby eliminating or reducing the visibility of human eyes to the metal mesh and improving the display effect.

As shown in FIG. 8, the first direction X is intersected with the second direction Y, for example, the first direction X may be vertical to the second direction Y. For example, the first direction X may be a horizontal direction of the touch display apparatus, and the second direction Y may be a longitudinal direction of the touch display apparatus; or the first direction X may be a row direction of pixel arrangement of the touch display apparatus, and the second direction Y may be a column direction of pixel arrangement of the touch display apparatus.

It should be noted that only the first direction X being a horizontal direction and the second direction Y being a longitudinal direction is taken as an example for illustration in a plurality of drawings in the disclosure. In the disclosure, the technical solutions obtained by rotating the drawings by 90 degrees also fall within the protection scope of the disclosure.

The first connecting part 512 and the second connecting part 522 are disposed in different metal layers of the touch structure at least at an intersection, that is, one of the first connecting part 512 and the second connecting part 522 is disposed in the first metal layer 610 and the other is disposed in the second metal layer 630, and the first connecting part 512 and the second connecting part 522 are separated at the intersection by an insulating layer 620, to prevent crosstalk of touch signals communicated on the first connecting part 512 and the second connecting part 522.

Exemplarily, the first connecting part 512 is disposed in the first metal layer 610, two driving electrodes 511 disposed in the first metal layer 610 and adjacent along a first direction X are directly connected through the first connecting part 512; the second connecting part 522 is disposed in the second metal layer 630, two sensing electrodes 521 disposed in the first metal layer 610 and adjacent along a second direction Y are connected with the second connecting part 522 respectively through different via holes 621 in the insulating layer 620, thereby realizing connection between two sensing electrodes 521.

Exemplarily, as shown in FIG. 8, FIG. 9A and FIG. 9B, the first connecting part 512 is disposed in the second metal layer 630, two driving electrodes 511 arranged in the first metal layer 610 and adjacent along a first direction X are connected with the first connecting part 512 respectively through different via holes 621 in the insulating layer 620, thereby realizing connection between two driving electrodes 511. The second connecting part 522 is disposed in the first metal layer 610, two sensing electrodes 521 disposed in the first metal layer 610 and adjacent along a second direction Y are directly connected through the second connecting part 522

The second connecting part 522 is disposed in the first metal layer 610, two sensing electrodes 521 disposed in the first metal layer 610 and adjacent along a second direction Y are directly connected through the second connecting part 522; the first connecting part 512 is disposed in the second metal layer 630, two driving electrodes 511 disposed in the first metal layer 610 and adjacent along a first direction X are connected with the first connecting part 512 respectively through different via holes 621 in the insulating layer 620, thereby realizing connection between two driving electrodes 511.

It should be noted that, in FIG. 9A and FIG. 9B, only the case in which the driving electrode 511, the second connecting part 522 and the sensing electrode 521 are disposed in the first metal layer 610 and the first connecting part 512 is disposed in the second metal layer 630 is taken as an example for illustration. The electrical connection mode and structural figures in 30) other cases can be derived without doubt in the same way and principle. In addition, the driving electrode 511 and the sensing electrode 521 are shown in different fill patterns, in order to distinguish different electrodes. The driving electrode 511 and the sensing electrode 521 can be formed with the same material and the same process.

In some embodiments, the area of the driving electrode 511 and/or the sensing electrode

35 521 may be 9 mm² to 25 mm², i.e., the area of at least one of the driving electrode 511 and the sensing electrode 521 may be 9 mm² to 25 mm². The area of the driving electrode 511 may be 9 mm² to 25 mm², or the area of the sensing electrode 521 may be 9 mm² to 25 mm², or the area of both the driving electrode 511 and the sensing electrode 521 may be 9 mm² to 25 mm². The area of 9 mm² to 25 mm² can be specifically 10 mm², 12 mm², 14 mm², 16 mm², 20 mm² or 23 mm².

When the shape of the driving electrode 511 is rhombic, the lengths of both sides of the driving electrode 511 may be 3 mm to 5 mm, for example, 3.2 mm, 3.8 mm, 4 mm, 4.3 mm or 4.7 mm. Exemplarily, the length of one side of a rhombic driving electrode is 3.8 mm, and the length of the other side of the rhombic driving electrode is 4.7 mm; or the length of one side of the rhombic driving electrode is 4 mm, and the length of the other side of the rhombic driving electrode is 4.5 mm.

In a display apparatus with a pixel density being greater than 500 PPI (pixels per inch), touch electrodes arranged in an array are designed in metal meshes with openings with a side length being less than 0.3 mm, which are not recognizable by human eyes, so that a problem of visibility of driving electrodes composed of a side length of 3-5 mm can be eliminated. For medium and large-sized display apparatuss with a pixel density being less than 400 PPI, since the area of the light emitting region of sub-pixels is large, the opening of the metal mesh 100 is limited by a resistance-capacitance load, and the side length of the minimum opening 100A of the touch electrode is generally greater than 0.3 mm, and the electrodes are easily recognized by human eyes. In exemplary embodiments of the disclosure, the touch structure 1000 employs an opening of an asymmetrical pattern surrounded by a plurality of metal sides. The metal mesh performs reflections in multiple directions to achieve a quasi-scattering effect when illuminated by strong light, thereby eliminating the visibility of the metal mesh 100.

In some embodiments, the line width of the metal wire 110 may be 1 μm to 20 μm, for example, 2 μm, 3.5 μm, 4.7 μm, 8 μm, 15 μm or 18 μm. The line width of the metal wire 110 refers to the width vertical to an extending direction of the metal wire 110. For example, when the metal wire 110 is a linear metal wire 110L, the width of the metal wire 110 is the width of its cross section; and when the metal wire 110 is an arc metal wire 110H, the width of the metal wire 110 is the width of a cross section, and the cross section is vertical to the tangent direction of the cut position.

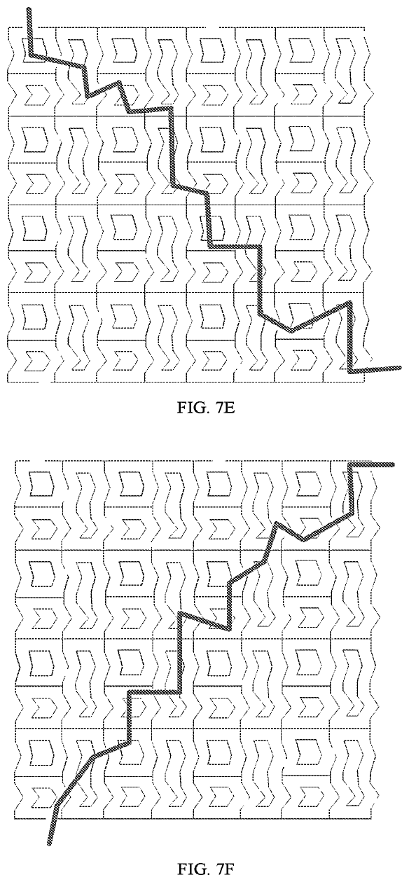

As shown in FIG. 10, some embodiments of the disclosure provide a display substrate 200, including: a base substrate 210 and a display functional layer 220 on the base substrate 210. The display functional layer 220 includes a plurality of sub-pixels 221, and the contour of a light emitting region of each sub-pixel has at least three different extending directions.

The above substrate 210 may be an organic substrate or an inorganic substrate. The material of the base substrate 210 may be polyethylene terephthalate (PET), polyimide (PI), cyclo olefin polymer (COP) or the like.

The display functional layer 220 may include a plurality of functional film layers forming the sub-pixels 221, for example, the respective film layers forming the thin film transistor 270, an anode 222, a light emitting layer 223, a cathode 224 and the like. The light emitting region 221A of the sub-pixel 221 can be understood as an effective light emitting surface of the sub-pixel 221, and the contour of the light emitting region 221A of each sub-pixel 221 has at least three different extending directions.

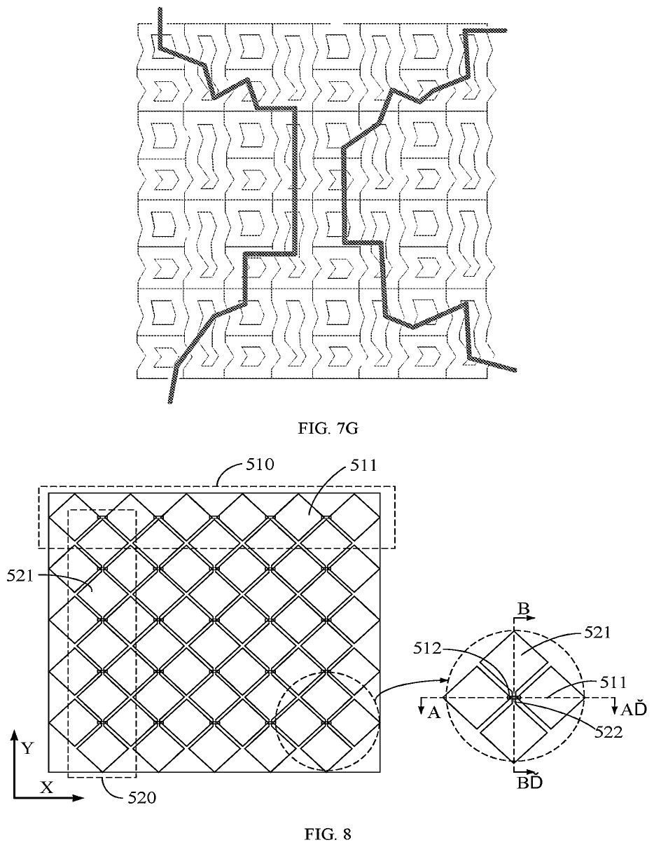

The light emitting regions 221A of the plurality of sub-pixels 221 may have the same asymmetrical pattern; or as shown in FIG. 11A to FIG. 11C, the light emitting regions 221A of the sub-pixels 221 of the same color may have the same shape, and the light emitting regions 221A of the sub-pixels 221 of different colors may have different shapes; or the light emitting regions 221A of the sub-pixels 221 of the same color may have different shapes and the light emitting regions 221A of the sub-pixels 221 of different colors may have different shapes; or the light emitting regions 221A of the sub-pixels 221 of different colors may also have the same shape.

Specifically, the lengths and angles of the three contour sides of the green sub-pixel G, the five contour sides of the red sub-pixel R and the seven contour sides of the blue sub-pixel B in an enlarged view shown in FIG. 11A are taken as an example for illustration.

The length of the contour side G1 is 20 μm and the included angle between the contour side G1 and the X direction is 60°, the length of the contour side G2 is 16 μm and the included angle between the contour side G2 and the X direction is 128°, and the length of the contour side G3 is 36 μm and the included angle between the contour side G3 and the X direction is 0°.

The length of the contour side R1 is 16 μm and the included angle between the contour side R1 and the X direction is 110°, the length of the contour side R2 is 12 μm and the included angle between the contour side R2 and the X direction is 50°, the length of the contour side R3 is 18 μm and the included angle between the contour side R3 and the X direction is 70°, the length of the contour side R4 is 20 μm and the included angle between the contour side R4 and the X direction is 103°, and the length of the contour side R5 is 36 μm and the included angle between the contour side R5 and the X direction is 0°.

The length of the contour side B1 is 22 μm and the included angle between the contour side B1 and the X direction is 60°, the length of the contour side B2 is 24 μm and the included angle between the contour side B2 and the X direction is 128°, the length of the contour side B3 is 24 μm and the included angle between the contour side B3 and the X direction is 110°, the length of the contour side B4 is 14 μm and the included angle between the contour side B4 and the X direction is 50°, the length of the contour side B5 is 18 μm and the included angle between the contour side B5 and the X direction is 70°, the length of the contour side B6 is 20 μm and the included angle between the contour side B6 and the X direction is 103°, and the length of the contour side B7 is 36 μm and the included angle between the contour side B7 and the X direction is 0°.

Specifically, the contour side G1 of the green sub-pixel G and the contour side R1 of the red sub-pixel R in an enlarged view shown in FIG. 11B are taken as an example for illustration. The included angle between the contour G1 and the Y direction is 0-90°, preferably, 0-45°; and the included angle between the contour side R1 and the Y direction is 0-90°, preferably, 0-45°.

Specifically, the contour side G1 of the green sub-pixel G and the contour side R1 of the red sub-pixel R in an enlarged view shown in FIG. 11C are taken as an example for illustration: the included angle between the contour side G1 and the Y direction is 0-90°, preferably, 0-45°.

Exemplarily, the light emitting region of the blue sub-pixel has one shape, the light emitting region of the red sub-pixel has a plurality of shapes, the light emitting region of the green sub-pixel has one shape, and the shapes of the light emitting regions of the sub-pixels of various colors are different from each other.

Exemplarily, the light emitting region of the blue sub-pixel has two shapes, the light emitting region of the red sub-pixel has two shapes, and the light emitting region of the green sub-pixel has one shape, where one shape of the light emitting region of the red sub-pixel is the same as one shape of the light emitting region of the blue sub-pixel, and other shapes are different from each other.

The asymmetrical patterns of the sub-pixels 221 may be different from or at least partially the same as the asymmetrical patterns of the openings 100A in the above metal mesh 100, which is not limited herein.

It should be noted that the shape of the contour side of the light emitting region 221A of the above sub-pixel 221 may include a linear segment, and may include an arc. The specific shape may refer to the shape of the opening 100A in FIG. 5.

The contour sides of the contour of the light emitting region 221A surrounding a sub-pixel 221 may be all linear contour sides, and may be all arc contour sides, or part of the contour sides may be linear contour sides and the remaining of the contour sides may be arc contour sides. When the contour sides surrounding the light emitting region 221A of the sub-pixel 221 are all linear contour sides, the light emitting region 221A of the sub-pixel 221 is an asymmetric polygon pixel (APP).

In some embodiments, the contour of the light emitting region 221A consists of N sides connected end to end, the N sides have M different extending directions; N and M are integers, and N≥5, 3≤M≤N.

Two sides having the same extending direction means that two sides are parallel to each other, and two sides having different extending directions means that two sides are intersected or the extending lines of two sides are intersected. Exemplarily, the number N of sides surrounding the light emitting region 221A may be 5, 7, 9, 10 or 15. For example, when the number of metal wires surrounding the opening 100A is 5, there may be 3 extending directions of five metal wires. When M is equal to N, the extending directions of N metal wires surrounding the opening are all different; and when M is less than N, the extending directions of at least two metal wires are the same.

In some embodiments, as shown in FIG. 11A, the shape of the light emitting region 221A of each sub-pixel is asymmetric.

In some embodiments, as shown in FIG. 11A, any two sides of the N edges are asymmetrical to each other. The asymmetry between two sides can be that the extending directions of two sides are symmetrical and the extending lengths are different; or the extending directions of two sides are asymmetrical and the extending lengths are the same; or the extending directions of the two sides are asymmetrical and the extending lengths are also different.

In some embodiments, as shown in FIG. 11B and FIG. 11C, the contour of at least part of the light emitting region 221A is a symmetrical pattern, where a center line of the contour along a row direction X of the light emitting region 221A which is a symmetrical patternis an axis of symmetry. Setting the contour of the light emitting region 221A to be a symmetrical pattern can increase the pixel aperture ratio.

The pixel defining layer 225 includes a first light outlet 225A1, a second light outlet 225A2 and a third light outlet 225A3.

Exemplarily, as shown in FIG. 11B and FIG. 11C, the first light outlet 225A1 and the second light outlet 225A2 are both in symmetrical patterns, a center line L1 of the first light outlet 225A1 along a row direction is an axis of symmetry, and a center line L2 of the second light outlet 225A2 along a row direction is an axis of symmetry.

In some embodiments, the display functional layer 220 includes sub-pixels 221 of a plurality of colors, and the contour of the light emitting region 221A of the sub-pixels 221 of at least one color is formed by more than eight sides connected end to end.

That is, the contours of the light emitting regions 221A of the sub-pixels 221 of one color all consist of more than eight sides connected end to end, the contours of the light emitting regions 221A of the sub-pixels 221 of the same color have the same shape; or the contours of the light emitting regions 221A of the sub-pixels 221 of this color may include a plurality of shapes, and the number of sides of each type of shape is more than eight. In the first case, the number of sides of the contours of the light emitting regions 221A of the sub-pixels 221 of this color is the same; or in the second case, the number of edges of the contours of the light emitting regions 221A of the sub-pixels 221 of this color may be different.

Exemplarily, the contours of the light emitting regions 221A of the blue sub-pixels 221 are all of an asymmetrical pattern with nine sides. In this case, the number of contour sides of the light emitting regions 221A of the blue sub-pixels 221 is all nine.

Exemplarily, the contours of the light emitting regions 221A of the blue sub-pixels 221 include an asymmetrical pattern with eight sides and an asymmetrical pattern with ten sides. In this case, the number of contour sides of the light emitting regions 221A of one part of the blue sub-pixels 221 is eight, and the number of contour sides of the light emitting regions 221A of the other part of the blue sub-pixels 221 is ten.

Exemplarily, the contours of the light emitting regions 221A of the blue sub-pixels 221 includes three different asymmetrical patterns with eight sides, and in this case, the number of contour sides of the light emitting regions 221A of the blue sub-pixels 221 is all eight.

In addition, the contours of the light emitting regions 221A of the sub-pixels 221 of multiple colors may consist of more than eight sides connected end to end, for example, the contours of the light emitting regions 221A of the sub-pixels 221 of two colors may consist of more than eight sides connected end to end, or the contours of the light emitting regions 221A of the sub-pixels 221 of all colors may consist of more than eight sides connected end to end. The case of the sub-pixels 221 of each color can be referred to the case in which the contours of the light emitting regions 221A of the sub-pixels 221 of the same color consists of by more than eight sides connected end to end, which is not repeated redundantly herein.

In some embodiments, the light emitting regions 221A of the sub-pixels 221 of different colors have different shapes and/or different areas.

A difference in shapes of the light emitting regions 221A of the sub-pixels 221 of different colors means that the shape of the light emitting region 221A of the sub-pixel 221 of one color is different from the shape of the light emitting region 221A of the sub-pixel 221 of other colors. Where the light emitting region 221A of the sub-pixel 221 of one color may have one or more shapes, when the light emitting region 221A of the sub-pixel 221 of one color has various shapes, the shape of the light emitting region 221A of the sub-pixel 221 of other colors is not the same as any of the various shapes.

Exemplarily, the shape of the light emitting region 221A of the sub-pixel 221 of one color includes shape 1 and shape 2, and any shape of the light emitting region 221A of the sub-pixel 221 of other colors is different from both shape 1 and shape 2.

A difference in the area of the light emitting region 221A of the sub-pixel 221 of different colors means that the area of the light emitting region of the sub-pixel 221 of one color is different from the area of the light emitting region 221A of the sub-pixel 221 of other colors. Where, the light emitting region 221A of the sub-pixel 221 of one color may have one or more types of areas. When the light emitting region 221A of the sub-pixel 221 of one color has various types of areas, the area of the light emitting region 221A of the sub-pixel 221 of other colors is not the same as any of the various areas.

Exemplarily, the area of the light emitting region 221A of the sub-pixel 221 of one color includes area 1 and area 2, while any area of the light emitting region 221A of the sub-pixel 221 of the other color is different from the area 1 and the area 2. The light emitting regions 221A of the sub-pixels 221 of different colors may be

different in shape and area, may be the same in shape but different in area, and may be different in shape but the same in area.

Exemplarily, the shape of the light emitting region of the blue sub-pixel is the same as the shape of the light emitting region of the red sub-pixel, but the area of the light emitting region of the blue sub-pixel is different from the area of the light emitting region of the red sub-pixel.

Exemplarily, the shape of the light emitting region of the blue sub-pixel is different from the shape of the light emitting region of the white sub-pixel, but the area of the light emitting region of the blue sub-pixel is the same as the area of the light emitting region of the white sub-pixel.

In some embodiments, as shown in FIG. 10, the display functional layer includes a pixel defining layer 225 which is provided with a plurality of light outlets 225A, each light outlet 225A determines a light emitting region 221A of a sub-pixel; and the shape of the light outlet 225A is approximately the same as the shape of the light emitting region 221A of the sub-pixel 221.

The structure of the pixel defining layer 225 is similar to a mesh. Multiple light outlets 225A are surrounded by a blocking dam. One sub-pixel region is provided therein with one light outlet 225A. The light outlet 225A is configured to determine the light emitting region 221A of the sub-pixel 221, and the light emitted from the light emitting layer 223 passes through the light outlet 225A, to form a light emitting region 221A. Therefore, the shape of the light outlet 225A is approximately the same as the shape of the light emitting region 221A of the sub-pixel 221.

The plurality of light outlets 225A of the light emitting regions 221A of the sub-pixels 221 of the same color in the pixel defining layer 225 may be of the same shape, and the light outlets 225A of the light emitting regions 221A of the sub-pixels 221 of different colors may be of different shapes.

In some embodiments, as shown in FIG. 11A, the display functional layer 220 includes a blue sub-pixel B, a red sub-pixel R, and a green sub-pixel G, where the area of the light emitting region 221A of the blue sub-pixel B is greater than the area of the light emitting region 221A of the red sub-pixel R, and the area of the light emitting region 221A of the red sub-pixel R is greater than the area of the light emitting region 221A of the green sub-pixel G.

As shown in FIG. 11B and FIG. 11C, the display functional layer 220 includes a blue sub-pixel B, a red sub-pixel R, and a green sub-pixel G, where the area of the light emitting region 221A of the blue sub-pixel B is greater than the area of the light emitting region 221A of the red sub-pixel R, and the area of the light emitting region 221A of the green sub-pixel G is greater than the area of the light emitting region 221A of the red sub-pixel R.

The pixel defining layer 225 includes a first light outlet 225A1, a second light outlet 225A2 and a third light outlet 225A3. The first light outlet 225A1 is configured to determine a light emitting region 221A of the blue sub-pixel B, the second light outlet 225A2 is configured to determine a light emitting region 221A of the red sub-pixel R, and the third light outlet 225A3 is configured to determine a light emitting region 221A of the green sub-pixel G.

The area of the opening of the first light outlet 225A1 is greater than the area of the opening of the second light outlet 225A2, and the area of the opening of the second light outlet 225A2 is greater than the area of the opening of the third light outlet 225A3.

It should be noted that the display functional layer 220 includes a blue sub-pixel B, a red sub-pixel R, and a green sub-pixel G, but is not limited to the sub-pixels of the above three colors, and may also include sub-pixels of other colors, such as a white sub-pixel. The above is only illustrated by using a blue sub-pixel, a red sub-pixel and a green sub-pixel as an example.

As shown in FIG. 11A, the first light outlet 225A1 of a plurality of light outlets 225A in the pixel defining layer 225 is located within the region of the blue sub-pixel B, and light emitted from the light emitting layer 223 of the blue sub-pixel B passes through the first light outlet 225A1 to form the light emitting region 221A of the blue sub-pixel B; the second light outlet 225A2 of a plurality of light outlets 225A in the pixel defining layer 225 is located within the region of the red sub-pixel R, and light emitted by the light emitting layer 223 of the red sub-pixel R passes through the second light outlet 225A2 to form the light emitting region 221A of the red sub-pixel R; and the third light outlet 225A3 of the plurality of light outlets 225A in the pixel defining layer 225 is located within the region of the green sub-pixel G, and the light 30) emitted from the light emitting layer 223 of the green sub-pixel G passes through the third light outlet 225A3 to form the light emitting region 221A of the green sub-pixel G.

The areas are designed in such a way that the area of the opening of the first light outlet 225A1 is greater than the area of the opening of the second light outlet 225A2 and the area of the opening of the second light outlet 225A2 is greater than the area of the opening of the third light outlet 225A3, so that the area of the light emitting region 221A of the blue sub-pixel B is greater than the area of the light emitting region 221A of the red sub-pixel R, and the area of the light emitting region 221A of the red sub-pixel R is greater than the area of the light emitting region 221A of the green sub-pixel G.

Human eyes have different sensitivity to color. The sensitivity of human eyes to color is specifically as follows: green>red>blue. Based on this, the area of the light emitting region 221A of the blue sub-pixel B is greater than the area of the light emitting region 221A of the red sub-pixel R, and the area of the light emitting region 221A of the red sub-pixel R is greater than the area of the light emitting region 221A of the green sub-pixel G, thereby realizing balance of perception of human eyes on light of various colors, reducing redundancy of sub-pixels and improving the aperture ratio and resolution.

As shown in FIG. 18, some embodiments of the disclosure also provide a display panel 900, including: a display substrate 200 as mentioned above and a touch structure 1000 as mentioned above, and the touch structure 1000 is disposed on a light emitting side of the display substrate 200.

As shown in FIG. 10, the display substrate 200 includes a base substrate 210 and a light emitting device 240 formed on the base substrate. The encapsulating layer 250 covers the light emitting device 240, and the touch structure 1000 is formed on the encapsulating layer 250. In some embodiments, when an anti-reflection structure (e.g. a circular polarizer) is further provided at the light emitting side of the display substrate 200, the touch structure 1000 is formed between the encapsulating layer 250 and the anti-reflection structure, and the metal mesh 100 may be formed directly on the surface of the encapsulating layer 250, i.e., no other film layer exists between the metal mesh 100 and the surface of the encapsulating layer 250.

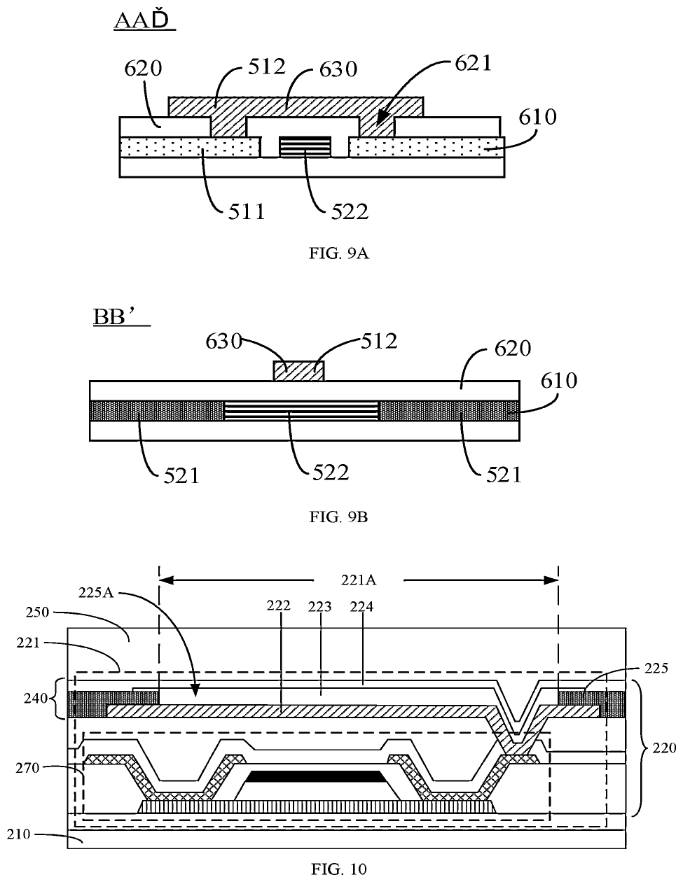

In some embodiments, as shown in FIG. 12A to FIG. 12C, an orthographic projection 221AT of the light emitting region 221A of at least one sub-pixel 221 of the display substrate 200 on the base substrate 210 of the display substrate 200 is located within an orthographic projection 100AT of an opening 100A of the metal mesh 110 of the touch structure 1000 on the base substrate 210 of the display substrate 200.

The shape of the orthographic projection 221AT of the light emitting region 221A of the sub-pixel 221 on the base substrate 210 is the same or approximately the same as the shape of the light emitting region 221A of the sub-pixel 221. Similarly, the shape of the opening 100A of the metal mesh 100 of the touch structure 1000 is the same or approximately the same as the shape of the orthographic projection 100AT of the opening 100A of the metal mesh 100 of the touch structure 1000 on the base substrate 210.

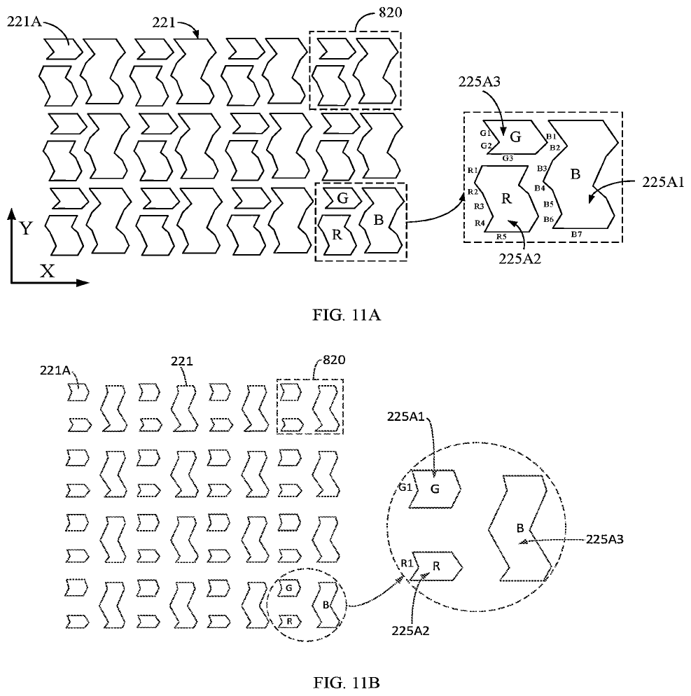

When the opening 100A is as shown in FIG. 3A to FIG. 3C, that is, at least one metal wire 110 of the plurality of metal wires 110 surrounding the opening 100A includes at least one cut 110A, the orthographic projection 221AT of the light emitting region 221A of the sub-pixel 221 corresponding to FIG. 12A to FIG. 12C on the base substrate 210 and the orthographic projection 221AT of the opening 100A on the base substrate 210 are shown in FIG. 13A to FIG. 13C.

An orthographic projection 221AT of the light emitting region 221A of at least one sub-pixel 221 on the base substrate 210 being located within an orthographic projection 100AT of an opening 100A of the metal mesh 100 on the base substrate 210 can be understood as that an orthographic projection of the light emitting region 221A of at least one sub-pixel 221 on the base substrate 210 is located in at least part of the region of an orthographic projection 100AT of an opening 100A of the metal mesh 100 on the base substrate 210.

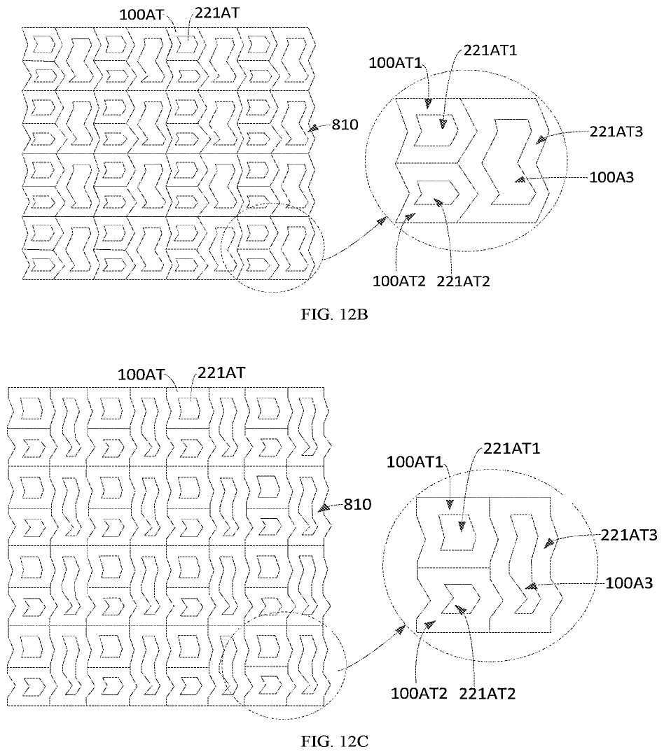

An orthographic projection 221AT of a light emitting region 221A of a sub-pixel 221 on the base substrate 210 is located within an orthographic projection 100AT of an opening 100A of the metal mesh 100 on the base substrate 210; or, an orthographic projection 221AT of the light emitting regions 221A of the plurality of sub-pixels 221 on the base substrate 210 is located within an orthographic projection of an opening 100A of the metal mesh 100 on the base substrate 210, as shown in FIG. 14; or the orthographic projections 221AT of the light emitting regions 221A of the plurality of sub-pixels 221 on the base substrate 210 are respectively located within orthographic projections 100AT of the plurality of openings 100A of the metal mesh 100 on the base substrate 210, as shown in FIG. 15.

Exemplarily, orthographic projections 221AT of the light emitting regions 221A of two sub-pixels 221 on the base substrate 210 are both located within an orthographic projection 100AT of an opening 100A of the metal mesh 100 on the base substrate 210, as shown in FIG. 14; or orthographic projections 221AT of the light emitting regions 221A of four sub-pixels 221 on the base substrate 210 are respectively located within orthographic projections 100AT of four openings 100A of the metal mesh 100 on the base substrate, as shown in FIG. 15.

In addition, the orthographic projections 221AT of the light emitting regions 221A of some sub-pixels 221 on the base substrate 210 may be at least partially coincided with orthographic projections 100AT of a plurality of openings 100A of the metal mesh 100 on the base substrate 210, respectively. That is, part of the orthographic projection 221AT of the light emitting region 221A of the sub-pixel 221 on the base substrate 210 is at least partially coincided with the orthographic projection 100AT of one opening 100A of the metal mesh 100 on the base substrate 210, and the other part of the orthographic projection 221AT of the light emitting region 221A of the sub-pixel 221 on the base substrate 210 is at least partially coincided with the orthographic projection 100AT of the other opening 100A of the metal mesh 100 on the base substrate 210.

In some embodiments, an orthographic projection 221AT of the light emitting region 221A of each sub-pixel 221 on the base substrate 210 is located within an orthographic projection 100AT of an opening 100A of the metal mesh 100 on the base substrate 210. That is, the orthographic projection of the light emitting region 221A of each sub-pixel 221 on the base substrate 210 is located in at least part of the region of the orthographic projection 100AT of one opening 100A of the metal mesh 100 on the base substrate 210.

The number of openings 100A of the metal mesh 100 of the touch structure 1000 may be equal to the number of sub-pixels 221 in the display substrate 200, and positions of the plurality of sub-pixels 221 in the display substrate 200 are in one-to-one correspondence with positions of the plurality of openings 100A of the metal mesh 100 of the touch structure 1000.

The shape of the orthographic projection 221AT of the light emitting region 221A of the sub-pixel 221 on the base substrate 210 may be the same as or different from the shape of the orthographic projection 100AT of the opening 100A of the metal mesh 100 on the base substrate 210, for example, the shape of the orthographic projection 221AT of the light emitting region 221A of the sub-pixel 221 on the base substrate 210 is a structure with 7 sides, and the shape of the orthographic projection 100AT of the opening 100A of the metal mesh 100 on the base substrate 210 is a structure with 9 sides; or the shape of the orthographic projection 221AT of the opening 100A of the metal mesh 100 on the base substrate 210 and the shape of the orthographic projection 100AT of the opening 100A of the metal mesh 100 on the base substrate 210 are two different structures each with 8 sides.

The orthographic projection 221AT of the light emitting region 221A of the sub-pixel 221 on the base substrate 210 may be located in a central region of the orthographic projection 100AT of the opening 100A of the metal mesh 100 on the base substrate 210; and the orthographic projection 221AT of the light emitting region 221A of the sub-pixel 221 on the base substrate 210 may also be located in an edge region of the orthographic projection 100AT of the opening 100A of the metal mesh 100 on the base substrate 210.

The contour of the orthographic projection 221AT of the light emitting region 221A of the sub-pixel 221 on the base substrate 210 may be at least partially coincided with the contour of the orthographic projection 100AT of the opening 100A of the metal mesh 100 on the base substrate 210. The contour of the orthographic projection 221AT of the light emitting region 221A of the sub-pixel 221 on the base substrate 210 may alternatively be not coincided with the contour of the orthographic projection 100AT of the opening 100A of the metal mesh 100 on the base substrate 210, that is, a gap 810 exists between the contour of the orthographic projection 221AT of the light emitting region 221A of the sub-pixel 221 on the base substrate 210 and the contour of the orthographic projection 100AT of the opening 100A of the metal mesh 100 on the base substrate 210, as shown in FIG. 12A to FIG. 16.

When the shape of the orthographic projection 221AT of the light emitting region 221A of the sub-pixel 221 on the base substrate 210 is different from the shape of the orthographic projection 100AT of the opening 100A of the metal mesh 100 on the base substrate 210, the gap 810 between the contour of the orthographic projection 221AT of the light emitting region 221A of the sub-pixel 221 on the base substrate 210 and the contour of the orthographic projection 100AT of the opening 100A of the metal mesh 100 on the base substrate 210 may differ in the gap width in different directions, as shown in FIG. 14 to FIG. 16, and the gap widths of the orthographic projection 221AT of the light emitting region 221A of the same sub-pixel 221 on the base substrate 210 are different in different directions from the orthographic projection 100AT of the opening 100A on the base substrate 210.

When the orthographic projection 221AT of the light emitting region 221A of the sub-pixel 221 on the base substrate 210 is located in the edge region of the orthographic projection 100AT of the opening 100A of the metal mesh 100 on the base substrate 210, the gap 810 between the contour of the orthographic projection 221AT of the light emitting region 221A of the sub-pixel 221 on the base substrate 210 and the contour of the orthographic projection 100AT of the opening 100A of the metal mesh 100 on the base substrate 210 may differ in the gap width in different directions.

When the shape of the orthographic projection 221AT of the light emitting region 221A of the sub-pixel 221 on the base substrate 210 is the same as the shape of the orthographic projection 100AT of the opening 100A of the metal mesh 100 on the base substrate 210, and the orthographic projection 221AT of the light emitting region 221A of the sub-pixel 221 on the base substrate 210 is located in the central region of the orthographic projection 100AT of the opening 100A of the metal mesh 100 on the base substrate 210, the gap widths of the gap 810 between the contour of the orthographic projection 221AT of the light emitting region 221A of the sub-pixel 221 on the base substrate 210 and the contour of the orthographic projection 100AT of the opening 100A of the metal mesh 100 on the base substrate 210 in different directions may be approximately the same, as shown in FIG. 12A to FIG. 13C.

The metal mesh 100 can be fitted with the structure of the conventional sub-pixels. When the shape of the conventional sub-pixels is a symmetrical structure, as shown in FIG. 14 to FIG. 16, the shape of the orthographic projection 221AT of the light emitting region 221A of the sub-pixel 221 on the base substrate 210 is different from the shape of the orthographic projection 100AT of the opening 100A of the metal mesh 100 on the base substrate 210. The metal mesh 100 may also be fitted with a sub-pixel structure whose shape corresponds to the shape of the opening 100A, that is, the shape of the orthographic projection 221AT of the light emitting region 221A of the sub-pixel 221 on the base substrate 210 is the same as the shape of the orthographic projection 100AT of the opening 100A of the metal mesh 100 on the base substrate 210, as shown in FIG. 12A to FIG. 13C.

Here, as to the gap 810 between the contour of an orthographic projection 221AT of the light emitting region 221A of the sub-pixel 221 in FIG. 12A to FIG. 13C on the base substrate 210 and the contour of an orthographic projection 100AT of the opening 100A of the metal mesh 100 on the base substrate 210, when the gap widths in different directions are approximately the same, the pixel area in the display panel 900 can be positively correlated with the area of the opening, and the aperture ratio and resolution can be further improved.

In some embodiments, a gap 810 exists between the contour of an orthographic projection 221AT of a light emitting region 221A of at least one sub-pixel 221 on the base substrate 210 and the contour of an orthographic projection 100AT of the opening 100A on the base substrate 210.

That is, the area of an orthographic projection 221AT of the light emitting region 221A of the sub-pixel 221 on the base substrate 210 is smaller than the area of an orthographic projection 100AT of the opening 100A on the base substrate 210, and the contour of an orthographic projection 221AT of the light emitting region 221A of the sub-pixel 221 on the base substrate 210 is located within the contour of an orthographic projection 100AT of the opening 100A on the base substrate 210 without intersection.

An orthographic projection 221AT of a light emitting region 221A of a sub-pixel 221 on the base substrate 210 is located within an orthographic projection 100AT of an opening 100A of the metal mesh 100 on the base substrate 210, and the contour of an orthographic projection 221AT of a light emitting region 221A of a sub-pixel 221 on the base substrate 210 is located within the contour of an orthographic projection 100AT of the opening 100A on the base substrate 210 without intersection.

Or, orthographic projections 221AT of the light emitting regions 221A of a plurality of sub-pixels 221 on the base substrate 210 are located within an orthographic projection 100AT of one opening 100A of the metal mesh 100 on the base substrate 210, and the contours of the orthographic projections 221AT of the light emitting regions 221A of the plurality of sub-pixels 221 on the base substrate 210 are not intersected with each other, and are located within the contour of the orthographic projection 100AT of the opening 100A on the base substrate 210 without intersection.

Or, orthographic projections 221AT of the light emitting regions 221A of a plurality of sub-pixels 221 on the base substrate 210 are respectively located within the orthographic projections 100AT of a plurality of openings 100A of the metal mesh 100 on the base substrate 210, and the contours of the orthographic projections 221AT of the light emitting regions 221A of each sub-pixel 221 on the base substrate 210 are located within the contours of the orthographic projections 100AT of the corresponding openings 100A on the base substrate 210 without intersection.

There is a gap 810 between the contour of the orthographic projection 221AT of the light emitting region 221A of the sub-pixel 221 on the base substrate 210 and the contour of the orthographic projection 100AT of the opening 100A on the base substrate 210, such that light emitted by the sub-pixel 221 is not blocked by the metal wire 110 of the metal mesh 100 of the touch structure 1000 on a light emitting side, thereby reducing or eliminating the mura phenomenon (the brightness display is uneven, and various traces are shown) on the display panel caused by the metal wire 110 blocking the light.

In some embodiments, as shown in FIG. 11A to FIG. 11C, the display substrate 200 includes a plurality of pixel units 820, each pixel unit 820 includes a plurality of sub-pixels 221; as shown in FIG. 1A to FIG. 1E, the metal mesh 100 includes a plurality of opening units 120, and each opening unit 120 includes one or more openings 100A.

Orthographic projections 221AT of light emitting regions 221A of a plurality of sub-pixels 221 of a pixel unit 820 on the base substrate 210 are located within an orthographic projection 100AT of one or more openings 100A of an opening unit 120 on the base substrate 210.

The number of sub-pixels 221 in one pixel unit 820 may be 3, 4, 5 or 6, which is not limited herein. Similarly, the number of openings 100A in one opening unit 120 may be 1, 3, 5 or 6, and the number of openings 100A in the opening unit 120 is not greater than the number of sub-pixels 221 in the pixel unit 820.

Exemplarily, the pixel unit 820 includes four sub-pixels 221, the opening unit 120 includes one opening 100A, and an orthographic projection 100AT of one opening 100A on the base substrate 210 covers orthographic projections 221AT of the light emitting regions 221A of the four sub-pixels 221 on the base substrate 210.

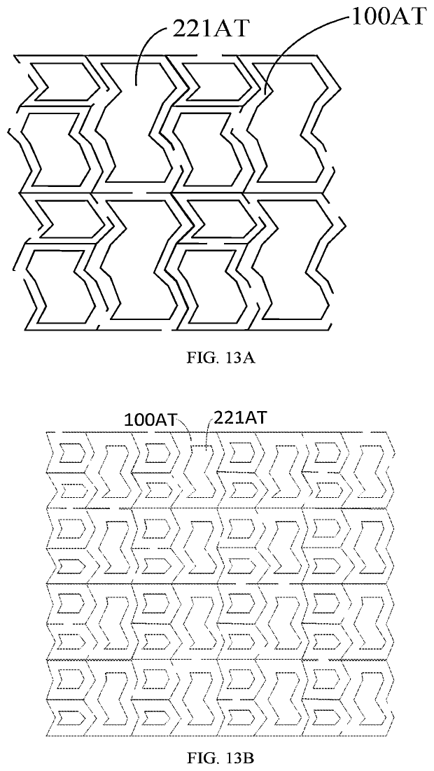

Exemplarily, the pixel unit 820 includes four sub-pixels 221, the opening unit 120 includes three openings 100A, an orthographic projection 100AT of one opening 100A on the base substrate 210 covers an orthographic projection 221AT of the light emitting region 221A of one sub-pixel 221 on the base substrate 210, an orthographic projection 100AT of another opening 100A on the base substrate 210 covers orthographic projections 221AT of the light emitting regions 221A of the other two sub-pixels 221 on the base substrate 210, and an orthographic projection 100AT of the remaining opening 100A on the base substrate 210 covers an orthographic projection 221AT of the light emitting region 221A of the remaining sub-pixel 221 on the base substrate 221A, as shown in FIG. 16.

In addition, the opening units 120 in the metal mesh 100 may be of multiple types, and the shapes of the openings 100A and the number of the openings 100A of the opening units 120 of different types may also be different. With the number of openings 100A of the opening units 120 of different types being different as an example, the pixel unit 820 includes four sub-pixels 221, the first type of opening units 120 includes two openings 100A and the second type of opening units 120 includes four openings 100A; in this way, orthographic projections of the light emitting regions 221A of four sub-pixels 221 in a pixel unit 820 on the base substrate 210 are located within orthographic projections 100AT of two openings 100A of the first type of opening units 120 on the base substrate 221, as shown in FIG. 14; and orthographic projections 221AT of the light emitting regions 221A of four sub-pixels 221 in the other pixel unit 820 on the base substrate 210 are located within orthographic projections 100AT of four openings 100A of the second type of opening units 120 on the base substrate 210, as shown in FIG. 15.

Orthographic projections 221AT of light emitting regions 221A of a plurality of sub-pixels 221 of a pixel unit 820 on the base substrate 210 being located within an orthographic projection of one or more openings 100A of an opening unit 120 on the base substrate 210 can be understood as that the position of the pixel unit 820 corresponds to the position of the opening unit 120 in the display panel. In this way, as to the arrangement of the plurality of opening units 120 in the touch structure 1000, please refer to the arrangement mode of the pixel units 820 on the display substrate 200.

In some embodiments, the pixel unit 820 includes a plurality of sub-pixels 221, and the opening unit 120 includes an opening 100A; and orthographic projections 221AT of the light emitting regions 221A of the plurality of sub-pixels 221 on the base substrate 210 are located within an orthographic projection 100AT of the opening 100A on the base substrate 210.

Exemplarily, the pixel unit 820 includes five sub-pixels 221. The opening unit 120 includes one opening 100A, and orthographic projections 221A of the light emitting regions 221A of five sub-pixels 221 in the same pixel unit 820 on the base substrate 210 are all located within an orthographic projection 100AT of the opening 100A on the base substrate 210.

In some embodiments, the pixel unit 820 includes a plurality of sub-pixels 221, and the opening unit 120 includes two openings 100A; an orthographic projection 221A of the light emitting region 221A of at least one sub-pixel 221 on the base substrate 210 is located within an orthographic projection of one of the openings 100A on the base substrate 210; and orthographic projections of the light emitting regions 221A of the remaining sub-pixels 221 on the base substrate 210 are located within an orthographic projection 100AT of the other opening 100A on the base substrate 210.

Exemplarily, the pixel unit 820 includes four sub-pixels 221. The opening unit 120 includes two openings 100A. An orthographic projection 100AT of one opening 100A on the base substrate 210 covers an orthographic projection 221AT of a light emitting region 221A of a sub-pixel 221 on the base substrate 210, and an orthographic projection 100A of the other opening 100A on the base substrate 210 covers orthographic projections 221AT of the light emitting regions 221A of the remaining three sub-pixels 221 on the base substrate 210; or an orthographic projection 100AT of one opening 100A on the base substrate 210 covers an orthographic projection 221AT of the light emitting regions 221A of two sub-pixels 221 on the base substrate 210, and an orthographic projection 100AT of the other opening 100A on the base substrate 210 covers orthographic projections 221AT of the light emitting regions 221A of the remaining two sub-pixels 221 on the base substrate 210, as shown in FIG. 14.

In some embodiments, the pixel unit 820 includes a plurality of sub-pixels 221, and the opening unit 120 includes three openings 100A; an orthographic projection 221A of the light emitting region 221A of at least one sub-pixel 221 on the base substrate 210 is located within an orthographic projection of one of the openings 100A on the base substrate 210; in addition, an orthographic projection 221A of the light emitting region 221A of at least one sub-pixel 221 on the base substrate 210 is located within an orthographic projection of the other opening 100A on the base substrate 210; and orthographic projections of the light emitting regions 221A of the remaining sub-pixels 221 on the base substrate 210 are located within an orthographic projection 100AT of the remaining opening 100A on the base substrate 210.

Exemplarily, as shown in FIG. 16, the pixel unit 820 includes four sub-pixels 221, and the opening unit 120 includes three openings 100A. An orthographic projection 100AT of an opening 100A on the base substrate 210 covers an orthographic projection 221AT of a light emitting region 221A of a sub-pixel 221 on the base substrate 210; an orthographic projection 100A of the other opening 100A on the base substrate 210 covers an orthographic projection 221AT of the light emitting region 221A of the other sub-pixel 221 on the base substrate 210; and an orthographic projection 100A of the remaining opening 100A on the base substrate 210 covers orthographic projections 221AT of the light emitting regions 221A of the remaining two sub-pixels 221 on the base substrate 210.

In some embodiments, the pixel unit 820 includes a plurality of sub-pixels 221, and the opening unit 120 includes four openings 100A; an orthographic projection 221A of the light emitting region 221A of at least one sub-pixel 221 on the base substrate 210 is located within an orthographic projection of the first opening 100A on the base substrate 210; in addition, an orthographic projection 221A of the light emitting region 221A of at least one sub-pixel 221 on the base substrate 210 is located within an orthographic projection of the second opening 100A on the base substrate 210; in addition, an orthographic projection 221A of the light emitting region 221A of at least one sub-pixel 221 on the base substrate 210 is located within an orthographic projection of the third opening 100A on the base substrate 210; and orthographic projections of the light emitting regions 221A of the remaining sub-pixels 221 on the base substrate 210 are located within an orthographic projection 100AT of a fourth opening 100A on the base substrate 210.

Exemplarily, as shown in FIG. 15, the pixel unit 820 includes four sub-pixels 221, and the opening unit 120 includes four openings 100A. An orthographic projection 100AT of the first opening 100A on the base substrate 210 covers an orthographic projection 221AT of a light emitting region 221A of a sub-pixel 221 on the base substrate 210; an orthographic projection 100A of the second opening 100A on the base substrate 210 covers an orthographic projection 221AT of the light emitting region 221A of the other sub-pixel 221 on the base substrate 210; an orthographic projection 100A of the third opening 100A on the base substrate 210 covers an orthographic projection 221AT of the light emitting region 221A of another sub-pixel 221 on the base substrate 210; and an orthographic projection 100A of the fourth opening 100A on the base substrate 210 covers an orthographic projection 221AT of the light emitting region 221A of the remaining sub-pixel 221 on the base substrate 210.

In some embodiments, as shown in FIG. 12A to FIG. 13C, the pixel unit 820 includes

sub-pixels 221 of X kinds of colors, and the opening unit 120 includes openings 100A of X types of shapes. The sub-pixels 221 of X kinds of colors are in one-to-one correspondence with the openings 100A of X types of shapes, X is an integer and X≥3.

A first orthographic projection 100AT of the opening 100A of the target shape on the base substrate 210 covers a second orthographic projection 221AT of the light emitting region 221A of the sub-pixel 221 of the target color on the base substrate 210; and the target shape is any shape among the X types of shapes, and the target color is a color corresponding to the target shape.

The shape of the first orthographic projection 100AT is approximately the same as the shape of the second orthographic projection 221AT, and there is a gap 810 between the contour of the second orthographic projection 221AT and the contour of the first orthographic projection 100AT.

The number of openings 100A in the opening unit 120 is equal to the number of sub-pixels 221 in the pixel unit 820, and the openings 100A of one type of shape in the opening unit 120 are in one-to-one correspondence with the sub-pixels 221 of one type of color in the pixel unit 820. The shapes of different openings 100A in the same opening unit 120 are different.

A first orthographic projection 100AT of the opening 100A of each shape on the base substrate 210 covers a second orthographic projection 221AT of the light emitting region 221A of the sub-pixel 221 of the color corresponding to the opening 100A of this shape on the base substrate 210.

Exemplarily, as shown in FIG. 12A to FIG. 12C, the pixel unit 820 includes a blue sub-pixel B, a red sub-pixel R and a green sub-pixel G; as shown in FIG. 1A to FIG. 1E, the opening unit 120 includes an opening 100A3 of a first shape corresponding to the blue sub-pixel B, an opening 100A2 of a second shape corresponding to the red sub-pixel R, and an opening 100A1 of a third shape corresponding to the green sub-pixel G. As shown in FIG. 12A to FIG. 12C, a first orthographic projection 100AT1 of the opening 100A3 of the first shape on the base substrate 210 covers a second orthographic projection 221AT3 of the light emitting region 221A of the blue sub-pixel B on the base substrate 210; a first orthographic projection 100AT2 of the opening 100A2 of a second shape on the base substrate 210 covers a second orthographic projection 221AT2 of the light emitting region 221A of the red sub-pixel R on the base substrate 210; and a first orthographic projection 100AT3 of the opening 100A3 of the third shape on the base substrate 210 covers a second orthographic projection 221AT3 of the light emitting region 221A of the green sub-pixel G on the base substrate 210.

In the above example, there may be one sub-pixel 221 of one type of color in one pixel unit 820, or there may be multiple sub-pixels 221 of one type of color in one pixel unit 820. For example, if two green sub-pixels 221 are included in one pixel unit 820, the first orthographic projection 100AT3 of the opening 100A3 of the third shape on the base substrate 210 covers the second orthographic projection 221AT3 of the light emitting regions 221A of two green sub-pixels G on the base substrate 210.

The shape of the first orthographic projection 100AT is approximately the same as the shape of the second orthographic projection 221AT, that is, the shape of the orthographic projection 100AT of the opening 100A of one shape on the base substrate 210 is approximately the same as the shape of the orthographic projection 221AT of the light emitting region 221A of the sub-pixel 221 of a corresponding color on the base substrate 210. It can be understood that the shape of an opening 100A is approximately the same as the shape of the sub-pixel 221 of the corresponding color. That is, not only the shapes of the openings 100A in the opening unit 120 are in one-to-one correspondence with the colors of the sub-pixels 221 in the pixel unit 820, but also the shapes of the openings 100A are approximately the same as the shapes of the sub-pixels 221 of the color corresponding to the openings 100A.

Exemplarily, the pixel unit 820 includes a blue sub-pixel 221 of a fourth shape, a red sub-pixel 221 of a fifth shape and a green sub-pixel 221 of a sixth shape; the opening unit 120 includes an opening 100A of a fourth shape corresponding to the blue sub-pixel 221, an opening 100A of a fifth shape corresponding to the red sub-pixel 221, and an opening 100A of a sixth shape corresponding to the green sub-pixel 221.

There is a gap 810 between the contour of the second orthographic projection 221AT and the contour of the first orthographic projection 100AT, i.e., among the openings 100A of the same shape and the sub-pixels 221, the area of the orthographic projection 100AT of the opening 100A on the base substrate 210 is greater than the area of the orthographic projection 221AT of the sub-pixel 221 on the base substrate 210, and the contour of the orthographic projection 221AT of the sub-pixel 221 on the base substrate 210 is located within the contour of the orthographic projection 100AT of the opening 100A on the base substrate 210 without intersection.

There is a gap 810 between the contour of the orthographic projection 221AT of the sub-pixel 221A on the base substrate 210 and the contour of the orthographic projection 100AT of the opening 100A on the base substrate 210, such that light emitted by the sub-pixel 221 is not blocked by the metal wire 110 surrounding the opening 100A on a light emitting side of the sub-pixel 221, thereby ensuring the light emitting efficiency of the display panel. Further, the shape of the opening 100A is approximately the same as the shape of the sub-pixel 221. Therefore, the width of the gap 810 in each direction between two contours which have the same shape and which are sleeved with each other can be uniform, thereby further enlarging the fabrication area of the sub-pixel while ensuring the light emitting efficiency of the display panel.

In some embodiments, a vertical interval (i.e., the width of the above gap 810) between the contour of the first orthographic projection 100AT and the contour of the second orthographic projection 221AT is 8 μm to 12 Ξm. In some embodiments, the spacing can be 9 μm, 10 μm, 10.3 Ξm, 11.1 μm or 11.8 μm.

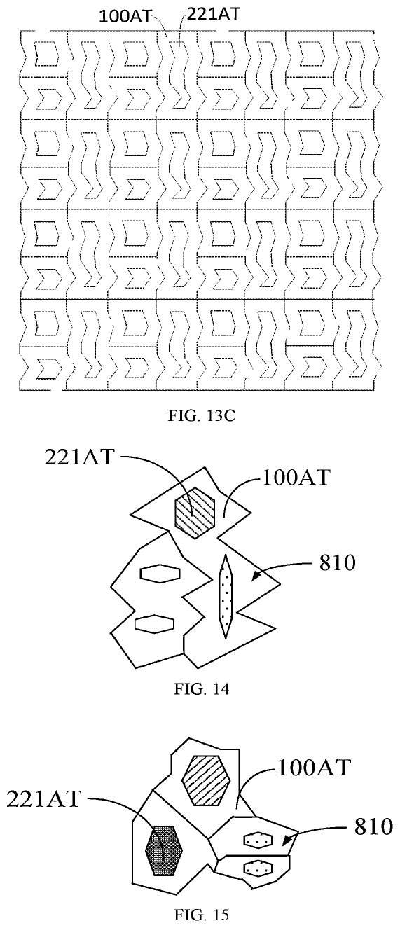

The above vertical interval may mean a linear distance between two points of intersection of a vertical line with two parallel lines which belong to two contours. Exemplarily, as shown in FIG. 17, line A is the line of the contour of the first orthographic projection 100AT, line B is the line of the contour of the second orthographic projection 221AT, line C is a vertical line vertical to line A and line B, point D is the point of intersection of line C and line A, point E is the point of intersection of line C and line B, and the vertical interval between line A and line B is a linear distance between point D and point E.

As shown in FIG. 19 and FIG. 20, the disclosure also provides a touch display apparatus including the above display panel 900. The beneficial effect achieved by the touch display apparatus is the same as the beneficial effect achieved by the display panel 900 in the above embodiment. The structure of the touch display apparatus has been described above, and will not be repeated redundantly herein.

The above mentioned are merely specific embodiments of the disclosure, but the protection scope of the disclosure is not limited thereto. Any variation or replacement conceived by those skilled in the art within the technical scope disclosed in the disclosure shall all fall within the protection scope of the disclosure. Therefore, the protection scope of the disclosure shall be subject to the protection scope of the claims.

1. A touch structure, comprising:
a metal mesh;
wherein the metal mesh comprises:
a plurality of metal wires; and
a plurality of openings, wherein each of the plurality of openings is surrounded by multiple metal wires of the plurality of metal wires, and the multiple metal wires surrounding each of the openings have at least three different extending directions.

2. The touch structure of claim 1, wherein the opening is surrounded by N metal wires connected end to end, and the N metal wires have M different extending directions;
wherein N and M are integers, N≥5, and 3≤M≤N.

3. The touch structure of claim 2, wherein a shape of each of the openings is asymmetric.

4. The touch structure of claim 3, wherein any two of the N metal wires are asymmetrical to each other.

5. The touch structure of claim 2, wherein at least part of the openings are symmetrical patterns; and
a center line along a row direction of the opening being of a symmetrical pattern is an axis of symmetry.

6. The touch structure of claim 5, wherein the metal wires surrounding the opening comprise at least one of:
two metal wires arranged in parallel with the center line; and
at least two groups of oblique metal wires arranged obliquely relative to the center line, wherein each group of oblique metal wires comprises two metal wires arranged in parallel;
or
at least two groups of vertical metal wires arranged vertically relative to the center line, wherein each group of the vertical metal wires comprises two metal wires arranged in parallel.

7. (canceled)

8. (canceled)

9. The touch structure of claim 6, wherein an included angle between the oblique metal wires and the vertical direction is greater than 0° and less than 45°.

10. The touch structure of claim 1, wherein the metal mesh comprises at least one type of openings, and each type of openings comprises a plurality of openings of a same shape, and different types of openings have different shapes.

11. The touch structure of claim 1, wherein the metal mesh comprises a plurality of opening units, each opening unit comprises one or more openings; and
at least one opening in the opening unit is surrounded by more than eight metal wires connected end to end.

12. The touch structure of claim 11, wherein the opening unit comprises at least three openings, and the at least three openings in the opening unit have different shapes and/or different areas.

13. The touch structure of claim 1, comprising at one of following:
a shape of the metal wire comprises a linear segment and/or an arc;
a width of the metal wire is 1 μm to 20 μm; or a material of the metal wire is copper, argentum, nano carbon or graphene.

14-16. (canceled)

17. The touch structure of claim 1, further comprising:
a plurality of touch electrodes;
wherein each touch electrode comprises a metal mesh, and the plurality of touch electrodes are configured to be independently connected with a touch chip.

18. The touch structure of claim 1, further comprising:
a plurality of driving units and a plurality of sensing units insulated from each other;
wherein each driving unit comprises a plurality of driving electrodes arranged side by side along a first direction and a first connecting part electrically connecting two adjacent driving electrodes;
each sensing unit comprises a plurality of sensing electrodes arranged side by side along a second direction and a second connecting part electrically connecting two adjacent sensing electrodes; and
the first direction and the second direction are intersected with each other;
the touch structure comprises:
a first metal layer, an insulating layer and a second metal layer which are stacked in sequence;
wherein
a plurality of via holes are arranged in the insulating layer;
the driving electrode, the first connecting part and the sensing electrode are disposed in one of the first metal layer and the second metal layer, the second connecting part is disposed in the other of the first metal layer and the second metal layer, and the second connecting part electrically connects two adjacent sensing electrodes through via holes; or
the driving electrode, the second connecting part and the sensing electrode are disposed in one of the first metal layer and the second metal layer, the first connecting part is disposed in the other of the first metal layer and the second metal layer, and the first connecting part electrically connects two adjacent driving electrodes through via holes; and
the driving electrode, the sensing electrode, the first connecting part and the second connecting part comprise metal meshes.

19. The touch structure of claim 18, wherein
an area of the driving electrode is 9 mm² to 25 mm²; and/or
an area of the sensing electrode is 9 mm² to 25 mm².

20. A display substrate, comprising:
a base substrate; and
a display functional layer on the base substrate;
wherein the display functional layer comprises a plurality of sub-pixels, and a contour of a light emitting region of each sub-pixel has sides in at least three different extending directions.

21. The display substrate of claim 20, wherein the contour of the light emitting region consists of N sides connected end to end, and the N sides have M different extending directions;
wherein N and M are integers, and N≥5, 3≤M≤N.

22. The display substrate of claim 21, wherein comprising at least one of following:
a shape of the light emitting region of each sub-pixel is asymmetric; or
any two of the N sides are asymmetrical to each other.

23-24. (canceled)

25. The display substrate of claim 20, wherein
the display functional layer comprises sub-pixels of a plurality of colors; and
a contour of the light emitting region of the sub-pixel of at least one color consists of more than eight sides connected end to end;
wherein light emitting regions of sub-pixels of different colors have different shapes and/or different areas.

26. (canceled)

27. The display substrate of claim 20, wherein the display functional layer comprises:
a pixel defining layer provided with a plurality of light outlets; wherein each light outlet determines a light emitting region of a sub-pixel; and
a shape of the light outlet is approximately same as a shape of the light emitting region of the sub-pixel;
wherein
the display functional layer comprises a blue sub-pixel, a red sub-pixel, and a green sub-pixel;
wherein
an area of a light emitting region of the blue sub-pixel is greater than an area of a light emitting region of the red sub-pixel; and
the area of the light emitting region of the red sub-pixel is greater than an area of a light emitting region of the green sub-pixel;
the pixel defining layer comprises a first light outlet, a second light outlet and a third light outlet;
wherein
the first light outlet is configured to determine a light emitting region of the blue sub-pixel;
the second light outlet is configured to determine a light emitting region of the red sub-pixel; and
the third light outlet is configured to determine a light emitting region of the green sub-pixel; and
an area of an opening of the first light outlet is greater than an area of an opening of the second light outlet; and
the area of the opening of the second light outlet is greater than an area of an opening of the third light outlet.

28. (canceled)

29. A display panel, comprising:
a display substrate of 28; and
a touch structure of disposed on a light emitting side of the display substrate;
wherein the display substrate comprises:
a base substrate; and
a display functional layer on the base substrate;
wherein the display functional layer comprises a plurality of sub-pixels, and a contour of a light emitting region of each sub-pixel has sides in at least three different extending directions wherein the touch structure comprises:
a metal mesh;
wherein the metal mesh comprises:
a plurality of metal wires; and
a plurality of openings, wherein each of the plurality of openings is surrounded by multiple metal wires of the plurality of metal wires, and the multiple metal wires surrounding each of the openings have at least three different extending directions.

30-36. (canceled)
